(19) United States
(12) Patent Application Publication
(10) Pub. No.: US 2026/0350252 A1
(43) Pub. Date: Nov. 5, 2026

(54) VIRTUAL-EXPERIENCE SIMULATION RECOVERY

(71) Applicant: Roblox Corporation, San Mateo, CA (US)

(72) Inventors: Linh Thi Xuan PHAN, Philadelphia, PA (US); Andreas HAEBERLEN, Philadelphia, PA (US); João Tiago Alves GONCALVES, San Mateo, CA (US); Yifan CAI, San Mateo, CA (US)

(73) Assignee: Roblox Corporation, San Mateo, CA (US)

(21) Appl. No.: 19/667,560

(22) Filed: May 4, 2026

Related U.S. Application Data
(60) Provisional application No. 63/800,040, filed on May 5, 2025.

(51) Int. Cl. G06F 30/13

(52) U.S. Cl. CPC G06F 30/13

(57) ABSTRACT

According to one aspect of the present disclosure, a computer-implemented method of a coordinator node is provided. The method includes: causing a first virtual-experience server to simulate a first region of a virtual 3D space and a second virtual-experience server to simulate a second region of the virtual 3D space; in response to the first frame and the another first frame corresponding to a first checkpoint interval, receiving first state information associated with the first frame from the first virtual-experience server and other first state information associated with the another first frame from the second virtual-experience server; and, in response to a failure of the second virtual-experience server before simulation of another second frame of the second region, causing the first virtual-experience server to perform recovery simulation for the second region based on the other first state information.

### CROSS-REFERENCE TO RELATED APPLICATION.S

This application is a non-provisional application that claims priority under 35 U.S.C. § 119(e) to U.S. Provisional Patent Application No. 63/800,040, filed on May. 5, 2025, the contents of which is hereby incorporated by reference herein in its entirety.

### TECHNICAL FIELD

Embodiments relate generally to online virtual experience platforms, and more particularly, to methods, systems, and computer readable media for simulation recovery.

### BACKGROUND

Online platforms, such as virtual-experience platforms and online-gaming platforms, can include client devices on which a user interacts with the virtual experience and virtual-experience servers, which manage the state of the virtual experience.

The background description provided herein is for the purpose of presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

According to one aspect of the present disclosure, a computer-implemented method of a coordinator node is provided. The method includes causing, by a processor, a first virtual-experience server to simulate a first zone of a virtual three-dimensional (3D) space and a second virtual-experience server to simulate a second zone of the virtual 3D space. At least one subzone of the second zone shares a boundary in the virtual 3D space with the first zone. The first virtual-experience server simulates a first frame of the first zone by running at least one first virtual-experience model using previous state information associated with a previous frame of the first zone. The second virtual-experience server simulates another first frame of the second zone by running at least one second virtual-experience model using other previous state information associated with another previous frame of the second zone. The method includes, in response to the first frame and the another first frame corresponding to a first checkpoint interval, receiving, by the processor, first state information associated with the first frame from the first virtual-experience server and other first state information associated with the another first frame from the second virtual-experience server. The method includes, in response to the first frame and the another first frame corresponding to a first checkpoint interval, includes storing, by the processor, the first state information and the other first state information. The method includes, in response to a failure of the second virtual-experience server before simulation of another second frame of the second zone, causing, by the processor, the first virtual-experience server to perform recovery simulation for the at least one subzone of the second zone based on the other first state information. The first virtual-experience server performs the recovery simulation by running the at least one second virtual-experience model using a portion of the other first state information corresponding to the at least one subzone.

In some implementations, by causing the first virtual-experience server to perform the recovery simulation for the at least one subzone of the second zone that shares the boundary with the first zone, no inter-zone messages associated with objects in the first zone and the at least one subzone of the second zone and used for simulation are sent over a network during simulation of the first zone and the at least one subzone after the recovery simulation.

In some implementations, each zone of the virtual 3D space includes a respective plurality of subzones. In some implementations, each subzone includes at least one region associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

In some implementations, the method includes receiving, by the processor, at least one inter-zone message associated with at least one object located in the second zone from a third virtual-experience server. In some implementations, the method includes storing, by the processor, the at least one inter-zone message until a subsequent checkpoint interval. In some implementations, causing the first virtual-experience server to perform the recovery simulation for the at least one subzone of the second zone includes sending, by the processor, the other first state information and the at least one inter-zone message to first virtual-experience server. In some implementations, the first virtual-experience server performs the recovery simulation of the another second frame of the second zone by running the at least one second virtual-experience model using the portion of the other first state information and the at least one inter-zone message.

In some implementations, causing the first virtual-experience server to perform the recovery simulation for the at least one subzone of the second zone includes determining, by the processor, the at least one subzone of the second zone shares the boundary with the first zone in the virtual 3D space. In some implementations, causing the first virtual-experience server to perform the recovery simulation for the at least one subzone of the second zone includes determining, by the processor, the first zone is assigned to the first virtual-experience server based on a registry that indicates assignments of virtual-experience servers to zones of the virtual 3D space. In some implementations, causing the first virtual-experience server to perform the recovery simulation for the at least one subzone of the second zone includes determining, by the processor, a first available workload capacity of the first virtual-experience server based on its simulation of the first zone. In some implementations, causing the first virtual-experience server to perform the recovery simulation for the at least one subzone of the second zone includes determining, by the processor, a maximum number of first contiguous subzones of the second zone that includes the at least one subzone. In some implementations, a first collective workload of the first contiguous subzones does not exceed the first available workload capacity of the first virtual-experience server. In some implementations, causing the first virtual-experience server to perform the recovery simulation for the at least one subzone of the second zone includes causing, by the processor, the first virtual-experience server to perform the recovery simulation for the maximum number of first contiguous subzones of the second zone.

In some implementations, the method includes causing, by the processor, a third virtual-experience server to simulate a third zone of the virtual 3D space. In some implementations, the method includes, in response to the failure of the second virtual-experience server before the simulation of another second frame of the second zone, causing, by the processor, the third virtual-experience server to perform recovery simulation for at least one other subzone of the second zone based on the other first state information. In some implementations, the third virtual-experience server performs the recovery simulation of the another second frame of the second zone by running the at least one second virtual-experience model using another portion of the other first state information corresponding to the at least one other subzone. In some implementations, the at least one other subzone of the second zone shares a boundary with the third zone in the virtual 3D space.

In some implementations, causing the third virtual-experience server to simulate the third zone of the virtual 3D space includes determining, by the processor, the at least one other subzone of the second zone shares the boundary with the third zone, the at least one other subzone being excluded from the maximum number of first contiguous subzones. In some implementations, causing the third virtual-experience server to simulate the third zone of the virtual 3D space includes determining, by the processor, the third zone is assigned to the third virtual-experience server based on the registry that indicates assignments of virtual-experience servers to zones of the virtual 3D space. In some implementations, causing the third virtual-experience server to simulate the third zone of the virtual 3D space includes determining, by the processor, a second available workload capacity of the third virtual-experience server. In some implementations, causing the third virtual-experience server to simulate the third zone of the virtual 3D space includes determining, by the processor, a maximum number of second contiguous subzones of the second zone that includes the at least one other subzone. In some implementations, a second collective workload of the second contiguous subzones does not exceed the second available workload capacity of the third virtual-experience server. In some implementations, causing the third virtual-experience server to simulate the third zone of the virtual 3D space includes causing, by the processor, the third virtual-experience server to perform the recovery simulation for the maximum number of second contiguous subzones of the second zone.

In some implementations, the method includes determining, by the processor, a recovery of the second virtual-experience server. In some implementations, the method includes, in response to the recovery of the second virtual-experience server, causing, by the processor, the second virtual-experience server to simulate the second zone of the virtual 3D space.

In some implementations, the method includes, after the first virtual-experience server performs the recovery simulation, determining, by the processor, a reduction in a workload capacity of the first virtual-experience server. In some implementations, the method includes, in response to the reduction in the workload capacity of the first virtual-experience server, causing, by the processor, a third virtual-experience server to simulate the at least one subzone of the second zone or at least one other subzone of the first zone.

In some implementations, the method includes receiving, by the processor, an indication of acceptance of the at least one subzone of the second zone for simulation from the first virtual-experience server. In some implementations, the method includes, in response to receiving the indication, sending, by the processor, a list of at least one other virtual-experience server that stores replicated state information for the at least one subzone of the second zone to the first virtual-experience server.

In some implementations, the method includes selecting, by the processor, a number of subzones per zone based on one or more of a target speed of simulation recovery or a number of frames associated with each checkpoint interval.

According to another aspect of the present disclosure, a computer-implemented method of a first virtual-experience server is provided. The method includes simulating, by a processor, a first frame of a first zone of a virtual 3Dspace by running at least one first virtual-experience model using previous state information associated with a previous frame of the first zone. The method includes, in response to the first frame corresponding to a first checkpoint interval, sending, by the processor, first state information associated with the first frame to a coordinator node. The method includes, in response to a failure of a second virtual-experience server before simulation of another first frame of a second zone, receiving, by the processor, a reassignment of at least one subzone of the second zone for simulation from the coordinator node. The at least one subzone shares a boundary with the first zone in the virtual 3D space. The method includes, in response to a failure of a second virtual-experience server before simulation of another first frame of a second zone, receiving, by the processor, other previous state information associated with another previous frame of the second zone from the coordinator node. The method includes, in response to a failure of a second virtual-experience server before simulation of another first frame of a second zone, performing, by the processor, a recovery simulation of the another first frame of the second zone by running a second virtual-experience model using a portion of the other previous state information corresponding to the at least one subzone.

In some implementations, by receiving the reassignment of the at least one subzone of the second zone that shares a boundary with the first zone, no inter-zone messages associated with objects in the first zone and the at least one subzone of the second zone and used for simulation are sent over a network during a subsequent simulation of the first zone and the at least one subzone.

In some implementations, each zone of the virtual 3D space comprises a plurality of subzones. In some implementations, each subzone comprises at least one region associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

In some implementations, the method includes, in response to the failure of the second virtual-experience server before simulation of the another first frame of the second zone, receiving, by the processor, at least one inter-zone message associated with at least one object located in the second zone from the coordinator node. In some implementations, performing the recovery simulation of the another first frame of the at least one subzone of the second zone includes simulating, by the processor, the another first frame of the at least one subzone of the second zone by running the second virtual-experience model using the portion of the other previous state information and the at least one inter-zone message.

In some implementations, the method includes, in response to a recovery of the second virtual-experience server, sending, by the processor, current state information associated with the at least one subzone of the second zone to one or more of the second virtual-experience server or the coordinator node.

In some implementations, the method includes, after performing the recovery simulation, determining, by the processor, a reduction in a workload capacity. In some implementations, the method includes, in response to the reduction in the workload capacity, sending a request to the coordinator node, by the processor, for a reassignment of one or more of subzones of the first zone or the second zone to another virtual-experience server.

In some implementations, the method includes sending, by the processor, an indication accepting the at least one subzone of the second zone for simulation to the coordinator node. In some implementations, the method includes receiving, by the processor and from the coordinator node, a list of at least one other virtual-experience server that stores replicated state information for the at least one subzone of the second zone from the coordinator node. In some implementations, the method includes sending, by the processor, the replicated state information for the at least one subzone of the second zone to the at least one other virtual-experience server.

According to a further aspect of the present disclosure, a computer-implemented method of a client device is provided. The method includes simulating, by a processor, a first frame of a first zone of a virtual 3D space by running at least one first virtual-experience model using previous state information associated with a previous frame of the first zone. The method includes, in response to a failure of a first virtual-experience server associated with the first zone, receiving, by the processor, an indication that a first subzone of the first zone is reassigned to a second virtual-experience server and a second subzone of the first zone is reassigned to a third virtual-experience server from a coordinator node. The method includes, in response to a failure of a first virtual-experience server associated with the first zone, sending, by the processor, first state information associated with the first frame of the first zone to the second virtual-experience server and the third virtual-experience server. The second virtual-experience server is assigned a first subzone of the first zone that shares a boundary with a second zone simulated by the second virtual-experience server. The third virtual-experience server is assigned a second subzone of the first zone that shares a boundary with a third zone simulated by the third virtual-experience server.

In some implementations, each zone of the virtual 3D space includes a plurality of subzones. In some implementations, each subzone comprises at least one region associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

According to still another aspect of the present disclosure, a computer-implemented method of a coordinator node is provided. The method includes causing, by a processor, a first virtual-experience server to simulate a first region of a virtual 3D space and a second virtual-experience server to simulate a second region of the virtual 3D space. The first virtual-experience server simulates a first frame of the first region by running at least one first virtual-experience model using previous state information associated with a previous frame of the first region. The second virtual-experience server simulates another first frame of the second region by running at least one second virtual-experience model using other previous state information associated with another previous frame of the second region. The method includes, in response to the first frame and the another first frame corresponding to a first checkpoint interval, receiving, by the processor, first state information associated with the first frame from the first virtual-experience server and other first state information associated with the another first frame from the second virtual-experience server. The method includes, in response to the first frame and the another first frame corresponding to a first checkpoint interval, storing, by the processor, the first state information and the other first state information. The method includes, in response to a failure of the second virtual-experience server before simulation of another second frame of the second region, causing, by the processor, the first virtual-experience server to perform recovery simulation for the second region based on the other first state information. The first virtual-experience server performs the recovery simulation by running the at least one second virtual-experience model using the other first state information.

In some implementations, each region is associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

In some implementations, the method includes receiving, by the processor, at least one inter-zone message associated with at least one object located in the second region from a third virtual-experience server. In some implementations, the method includes storing, by the processor, the at least one inter-zone message until a subsequent checkpoint interval.

In some implementations, causing the first virtual-experience server to perform the recovery simulation for the second region includes sending, by the processor, the other first state information and the at least one inter-zone message to first virtual-experience server. In some implementations, causing the first virtual-experience server to perform the recovery simulation for the second region includes causing, by the processor, the first virtual-experience server to perform recovery simulation for the second region based on the other first state information and the at least one inter-zone message. In some implementations, the first virtual-experience server performs the recovery simulation by running the at least one second virtual-experience model using the other first state information and the at least one inter-zone message.

In some implementations, the method includes in response to receiving the first state information and the other first state information, deleting, by the processor, the previous state information and the other previous state information. In some implementations, the previous state information and the other previous state information are associated with a previous checkpoint interval.

In some implementations, the method includes receiving, by the processor, an indication of acceptance of the second region for simulation from the first virtual-experience server. In some implementations, the method includes, in response to receiving the indication, sending, by the processor, a list of at least one other virtual-experience server that stores replicated state information for the second region of the virtual 3D space to the first virtual-experience server.

In some implementations, the method includes, in response to the failure of the second virtual-experience server, sending, by the processor, an indication that the second region of the virtual 3D space is reassigned to the first virtual-experience server to at least one client device simulating the second region.

In some implementations, the coordinator node includes one or more virtual 3D space servers. In some implementations, the coordinator node includes one or more storage devices.

According to still a further aspect of the present disclosure, a computer-implemented method of a virtual-experience server is provided. The method includes simulating, by a processor, a first frame of a first region of a virtual 3D space by running at least one first virtual-experience model using previous state information associated with a previous frame of the first region. The method includes, in response to the first frame corresponding to a first checkpoint interval, sending, by the processor, first state information associated with the first frame to a coordinator node. The method includes, in response to a failure of a second virtual-experience server before simulation of another first frame of a second region, receiving, by the processor, a reassignment of the second region for simulation from the coordinator node. The method includes, in response to a failure of a second virtual-experience server before simulation of another first frame of a second region, receiving, by the processor, other previous state information associated with another previous frame of the second region from the coordinator node. The method includes, in response to a failure of a second virtual-experience server before simulation of another first frame of a second region, performing, by the processor, a recovery simulation of the second region by running a second virtual-experience model using the other previous state information.

In some implementations, each region of the virtual 3D space is associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

In some implementations, the method includes, in response to the failure of the second virtual-experience server before simulation of the another first frame of the second region, receiving, by the processor, at least one inter-region message associated with at least one object located in the second region from the coordinator node. In some implementations, performing the recovery simulation of the second region includes simulating, by the processor, the another first frame of the second region by running the second virtual-experience model using the other previous state information and the at least one inter-region message.

In some implementations, the method includes, in response to a recovery of the second virtual-experience server, sending, by the processor, current state information associated with the second region to one or more of the second virtual-experience server or the coordinator node.

In some implementations, the method includes, after performing the recovery simulation, determining, by the processor, a reduction in a workload capacity. In some implementations, the method includes, in response to the reduction in the workload capacity, requesting, by the processor, a reassignment of one or more of the first region or the second region to another virtual-experience server.

In some implementations, the method includes sending, by the processor, an indication of acceptance of the second region for simulation to the coordinator node. In some implementations, the method includes, in response to the coordinator node receiving the indication, receiving, by the processor, a list of at least one other virtual-experience server that stores replicated state information for the second region from the coordinator node. In some implementations, the method includes sending, by the processor, the replicated state information for the second region to the at least one other virtual-experience server.

According to yet another aspect of the present disclosure, a computer-implemented method of a client device is provided. The method includes simulating, by a processor, a first frame of a first region of a virtual 3D space by running at least one first virtual-experience model using previous state information associated with a previous frame of the first region. The method includes, in response to a failure of a first virtual-experience server associated with the first region, receiving, by the processor, an indication that the first region is reassigned to a second virtual-experience server. The method includes, in response to a failure of a first virtual-experience server associated with the first region, sending, by the processor, first state information associated with the first frame of the first region to the second virtual-experience server.

In some implementations, each region is associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

According to one aspect of the present disclosure, a computing device of a coordinator node is provided. The computing device may include a processor and memory storing instructions, which when executed by a processor, cause the processor to perform operations. The operations include causing, by a processor, a first virtual-experience server to simulate a first zone of a virtual 3D space and a second virtual-experience server to simulate a second zone of the virtual 3D space. At least one subzone of the second zone shares a boundary in the virtual 3D space with the first zone. The first virtual-experience server simulates a first frame of the first zone by running at least one first virtual-experience model using previous state information associated with a previous frame of the first zone. The second virtual-experience server simulates another first frame of the second zone by running at least one second virtual-experience model using other previous state information associated with another previous frame of the second zone. The operations include, in response to the first frame and the another first frame corresponding to a first checkpoint interval, receiving, by the processor, first state information associated with the first frame from the first virtual-experience server and other first state information associated with the another first frame from the second virtual-experience server. The operations include, in response to the first frame and the another first frame corresponding to a first checkpoint interval, includes storing, by the processor, the first state information and the other first state information. The operations include, in response to a failure of the second virtual-experience server before simulation of another second frame of the second zone, causing, by the processor, the first virtual-experience server to perform recovery simulation for the at least one subzone of the second zone based on the other first state information. The first virtual-experience server performs the recovery simulation by running the at least one second virtual-experience model using a portion of the other first state information corresponding to the at least one subzone.

In some implementations, by causing the first virtual-experience server to perform the recovery simulation for the at least one subzone of the second zone that shares the boundary with the first zone, no inter-zone messages associated with objects in the first zone and the at least one subzone of the second zone and used for simulation are sent over a network during simulation of the first zone and the at least one subzone after the recovery simulation.

In some implementations, each zone of the virtual 3D space includes a respective plurality of subzones. In some implementations, each subzone includes at least one region associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

In some implementations, the operations include receiving, by the processor, at least one inter-zone message associated with at least one object located in the second zone from a third virtual-experience server. In some implementations, the operations include storing, by the processor, the at least one inter-zone message until a subsequent checkpoint interval. In some implementations, causing the first virtual-experience server to perform the recovery simulation for the at least one subzone of the second zone includes sending, by the processor, the other first state information and the at least one inter-zone message to first virtual-experience server. In some implementations, the first virtual-experience server performs the recovery simulation of the another second frame of the second zone by running the at least one second virtual-experience model using the portion of the other first state information and the at least one inter-zone message.

In some implementations, causing the first virtual-experience server to perform the recovery simulation for the at least one subzone of the second zone includes determining, by the processor, the at least one subzone of the second zone shares the boundary with the first zone in the virtual 3D space. In some implementations, causing the first virtual-experience server to perform the recovery simulation for the at least one subzone of the second zone includes determining, by the processor, the first zone is assigned to the first virtual-experience server based on a registry that indicates assignments of virtual-experience servers to zones of the virtual 3D space. In some implementations, causing the first virtual-experience server to perform the recovery simulation for the at least one subzone of the second zone includes determining, by the processor, a first available workload capacity of the first virtual-experience server based on its simulation of the first zone. In some implementations, causing the first virtual-experience server to perform the recovery simulation for the at least one subzone of the second zone includes determining, by the processor, a maximum number of first contiguous subzones of the second zone that includes the at least one subzone. In some implementations, a first collective workload of the first contiguous subzones does not exceed the first available workload capacity of the first virtual-experience server. In some implementations, causing the first virtual-experience server to perform the recovery simulation for the at least one subzone of the second zone includes causing, by the processor, the first virtual-experience server to perform the recovery simulation for the maximum number of first contiguous subzones of the second zone.

In some implementations, the operations include causing, by the processor, a third virtual-experience server to simulate a third zone of the virtual 3D space. In some implementations, the operations include, in response to the failure of the second virtual-experience server before the simulation of another second frame of the second zone, causing, by the processor, the third virtual-experience server to perform recovery simulation for at least one other subzone of the second zone based on the other first state information. In some implementations, the third virtual-experience server performs the recovery simulation of the another second frame of the second zone by running the at least one second virtual-experience model using another portion of the other first state information corresponding to the at least one other subzone. In some implementations, the at least one other subzone of the second zone shares a boundary with the third zone in the virtual 3D space.

In some implementations, causing the third virtual-experience server to simulate the third zone of the virtual 3D space includes determining, by the processor, the at least one other subzone of the second zone shares the boundary with the third zone, the at least one other subzone being excluded from the maximum number of first contiguous subzones. In some implementations, causing the third virtual-experience server to simulate the third zone of the virtual 3D space includes determining, by the processor, the third zone is assigned to the third virtual-experience server based on the registry that indicates assignments of virtual-experience servers to zones of the virtual 3D space. In some implementations, causing the third virtual-experience server to simulate the third zone of the virtual 3D space includes determining, by the processor, a second available workload capacity of the third virtual-experience server. In some implementations, causing the third virtual-experience server to simulate the third zone of the virtual 3D space includes determining, by the processor, a maximum number of second contiguous subzones of the second zone that includes the at least one other subzone. In some implementations, a second collective workload of the second contiguous subzones does not exceed the second available workload capacity of the third virtual-experience server. In some implementations, causing the third virtual-experience server to simulate the third zone of the virtual 3D space includes causing, by the processor, the third virtual-experience server to perform the recovery simulation for the maximum number of second contiguous subzones of the second zone.

In some implementations, the operations include determining, by the processor, a recovery of the second virtual-experience server. In some implementations, the operations include, in response to the recovery of the second virtual-experience server, causing, by the processor, the second virtual-experience server to simulate the second zone of the virtual 3D space.

In some implementations, the operations include, after the first virtual-experience server performs the recovery simulation, determining, by the processor, a reduction in a workload capacity of the first virtual-experience server. In some implementations, the operations include, in response to the reduction in the workload capacity of the first virtual-experience server, causing, by the processor, a third virtual-experience server to simulate the at least one subzone of the second zone or at least one other subzone of the first zone.

In some implementations, the operations include receiving, by the processor, an indication of acceptance of the at least one subzone of the second zone for simulation from the first virtual-experience server. In some implementations, the operations include, in response to receiving the indication, sending, by the processor, a list of at least one other virtual-experience server that stores replicated state information for the at least one subzone of the second zone to the first virtual-experience server.

In some implementations, the operations include selecting, by the processor, a number of subzones per zone based on one or more of a target speed of simulation recovery or a number of frames associated with each checkpoint interval.

According to another aspect of the present disclosure, a computing device of a first virtual-experience server is provided. The computing device may include a processor and memory storing instructions, which when executed by a processor, cause the processor to perform operations. The operations include simulating, by a processor, a first frame of a first zone of a virtual 3Dspace by running at least one first virtual-experience model using previous state information associated with a previous frame of the first zone. The operations include, in response to the first frame corresponding to a first checkpoint interval, sending, by the processor, first state information associated with the first frame to a coordinator node. The operations include, in response to a failure of a second virtual-experience server before simulation of another first frame of a second zone, receiving, by the processor, a reassignment of at least one subzone of the second zone for simulation from the coordinator node. The at least one subzone shares a boundary with the first zone in the virtual 3D space. The operations include, in response to a failure of a second virtual-experience server before simulation of another first frame of a second zone, receiving, by the processor, other previous state information associated with another previous frame of the second zone from the coordinator node. The operations include, in response to a failure of a second virtual-experience server before simulation of another first frame of a second zone, performing, by the processor, a recovery simulation of the another first frame of the second zone by running a second virtual-experience model using a portion of the other previous state information corresponding to the at least one subzone.

In some implementations, by receiving the reassignment of the at least one subzone of the second zone that shares a boundary with the first zone, no inter-zone messages associated with objects in the first zone and the at least one subzone of the second zone and used for simulation are sent over a network during a subsequent simulation of the first zone and the at least one subzone.

In some implementations, each zone of the virtual 3D space comprises a plurality of subzones. In some implementations, each subzone comprises at least one region associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

In some implementations, the operations include, in response to the failure of the second virtual-experience server before simulation of the another first frame of the second zone, receiving, by the processor, at least one inter-zone message associated with at least one object located in the second zone from the coordinator node. In some implementations, performing the recovery simulation of the another first frame of the at least one subzone of the second zone includes simulating, by the processor, the another first frame of the at least one subzone of the second zone by running the second virtual-experience model using the portion of the other previous state information and the at least one inter-zone message.

In some implementations, the operations include, in response to a recovery of the second virtual-experience server, sending, by the processor, current state information associated with the at least one subzone of the second zone to one or more of the second virtual-experience server or the coordinator node.

In some implementations, the operations include, after performing the recovery simulation, determining, by the processor, a reduction in a workload capacity. In some implementations, the operations include, in response to the reduction in the workload capacity, sending a request to the coordinator node, by the processor, for a reassignment of one or more of subzones of the first zone or the second zone to another virtual-experience server.

In some implementations, the operations include sending, by the processor, an indication accepting the at least one subzone of the second zone for simulation to the coordinator node. In some implementations, the operations include receiving, by the processor and from the coordinator node, a list of at least one other virtual-experience server that stores replicated state information for the at least one subzone of the second zone from the coordinator node. In some implementations, the operations include sending, by the processor, the replicated state information for the at least one subzone of the second zone to the at least one other virtual-experience server.

According to a further aspect of the present disclosure, a computing device of a client device is provided. The computing device may include a processor and memory storing instructions, which when executed by a processor, cause the processor to perform operations. The operations include simulating, by a processor, a first frame of a first zone of a virtual 3D space by running at least one first virtual-experience model using previous state information associated with a previous frame of the first zone. The operations include, in response to a failure of a first virtual-experience server associated with the first zone, receiving, by the processor, an indication that a first subzone of the first zone is reassigned to a second virtual-experience server and a second subzone of the first zone is reassigned to a third virtual-experience server from a coordinator node. The operations include, in response to a failure of a first virtual-experience server associated with the first zone, sending, by the processor, first state information associated with the first frame of the first zone to the second virtual-experience server and the third virtual-experience server. The second virtual-experience server is assigned a first subzone of the first zone that shares a boundary with a second zone simulated by the second virtual-experience server. The third virtual-experience server is assigned a second subzone of the first zone that shares a boundary with a third zone simulated by the third virtual-experience server.

In some implementations, each zone of the virtual 3D space includes a plurality of subzones. In some implementations, each subzone comprises at least one region associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

According to still another aspect of the present disclosure, a computing device of a coordinator node is provided. The computing device may include a processor and memory storing instructions, which when executed by a processor, cause the processor to perform operations. The operations include causing, by a processor, a first virtual-experience server to simulate a first region of a virtual 3D space and a second virtual-experience server to simulate a second region of the virtual 3D space. The first virtual-experience server simulates a first frame of the first region by running at least one first virtual-experience model using previous state information associated with a previous frame of the first region. The second virtual-experience server simulates another first frame of the second region by running at least one second virtual-experience model using other previous state information associated with another previous frame of the second region. The operations include, in response to the first frame and the another first frame corresponding to a first checkpoint interval, receiving, by the processor, first state information associated with the first frame from the first virtual-experience server and other first state information associated with the another first frame from the second virtual-experience server. The operations include, in response to the first frame and the another first frame corresponding to a first checkpoint interval, storing, by the processor, the first state information and the other first state information. The operations include, in response to a failure of the second virtual-experience server before simulation of another second frame of the second region, causing, by the processor, the first virtual-experience server to perform recovery simulation for the second region based on the other first state information. The first virtual-experience server performs the recovery simulation by running the at least one second virtual-experience model using the other first state information.

In some implementations, each region is associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

In some implementations, the operations include receiving, by the processor, at least one inter-zone message associated with at least one object located in the second region from a third virtual-experience server. In some implementations, the operations include storing, by the processor, the at least one inter-zone message until a subsequent checkpoint interval.

In some implementations, causing the first virtual-experience server to perform the recovery simulation for the second region includes sending, by the processor, the other first state information and the at least one inter-zone message to first virtual-experience server. In some implementations, causing the first virtual-experience server to perform the recovery simulation for the second region includes causing, by the processor, the first virtual-experience server to perform recovery simulation for the second region based on the other first state information and the at least one inter-zone message. In some implementations, the first virtual-experience server performs the recovery simulation by running the at least one second virtual-experience model using the other first state information and the at least one inter-zone message.

In some implementations, the operations include in response to receiving the first state information and the other first state information, deleting, by the processor, the previous state information and the other previous state information. In some implementations, the previous state information and the other previous state information are associated with a previous checkpoint interval.

In some implementations, the operations include receiving, by the processor, an indication of acceptance of the second region for simulation from the first virtual-experience server. In some implementations, the operations include, in response to receiving the indication, sending, by the processor, a list of at least one other virtual-experience server that stores replicated state information for the second region of the virtual 3D space to the first virtual-experience server.

In some implementations, the operations include, in response to the failure of the second virtual-experience server, sending, by the processor, an indication that the second region of the virtual 3D space is reassigned to the first virtual-experience server to at least one client device simulating the second region.

In some implementations, the coordinator node includes one or more virtual 3D space servers. In some implementations, the coordinator node includes one or more storage devices.

According to still a further aspect of the present disclosure, a computing device of a virtual-experience server is provided. The computing device may include a processor and memory storing instructions, which when executed by a processor, cause the processor to perform operations. The operations include simulating, by a processor, a first frame of a first region of a virtual 3D space by running at least one first virtual-experience model using previous state information associated with a previous frame of the first region. The operations include, in response to the first frame corresponding to a first checkpoint interval, sending, by the processor, first state information associated with the first frame to a coordinator node. The operations include, in response to a failure of a second virtual-experience server before simulation of another first frame of a second region, receiving, by the processor, a reassignment of the second region for simulation from the coordinator node. The operations include, in response to a failure of a second virtual-experience server before simulation of another first frame of a second region, receiving, by the processor, other previous state information associated with another previous frame of the second region from the coordinator node. The operations include, in response to a failure of a second virtual-experience server before simulation of another first frame of a second region, performing, by the processor, a recovery simulation of the second region by running a second virtual-experience model using the other previous state information.

In some implementations, each region of the virtual 3D space is associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

In some implementations, the operations include, in response to the failure of the second virtual-experience server before simulation of the another first frame of the second region, receiving, by the processor, at least one inter-region message associated with at least one object located in the second region from the coordinator node. In some implementations, performing the recovery simulation of the second region includes simulating, by the processor, the another first frame of the second region by running the second virtual-experience model using the other previous state information and the at least one inter-region message.

In some implementations, the operations include, in response to a recovery of the second virtual-experience server, sending, by the processor, current state information associated with the second region to one or more of the second virtual-experience server or the coordinator node.

In some implementations, the operations include, after performing the recovery simulation, determining, by the processor, a reduction in a workload capacity. In some implementations, the operations include, in response to the reduction in the workload capacity, requesting, by the processor, a reassignment of one or more of the first region or the second region to another virtual-experience server.

In some implementations, the operations include sending, by the processor, an indication of acceptance of the second region for simulation to the coordinator node. In some implementations, the operations include, in response to the coordinator node receiving the indication, receiving, by the processor, a list of at least one other virtual-experience server that stores replicated state information for the second region from the coordinator node. In some implementations, the operations include sending, by the processor, the replicated state information for the second region to the at least one other virtual-experience server.

According to yet another aspect of the present disclosure, a computing device of a client device is provided. The computing device may include a processor and memory storing instructions, which when executed by a processor, cause the processor to perform operations. The operations include simulating, by a processor, a first frame of a first region of a virtual 3D space by running at least one first virtual-experience model using previous state information associated with a previous frame of the first region. The operations include, in response to a failure of a first virtual-experience server associated with the first region, receiving, by the processor, an indication that the first region is reassigned to a second virtual-experience server. The operations include, in response to a failure of a first virtual-experience server associated with the first region, sending, by the processor, first state information associated with the first frame of the first region to the second virtual-experience server.

In some implementations, each region is associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

According to one aspect of the present disclosure, a non-transitory computer-readable medium storing instructions for a coordinator node is provided. The instructions, which when executed by a processor of the coordinator node, cause the processor the coordinator node to perform operations. The operations include causing, by a processor, a first virtual-experience server to simulate a first zone of a virtual 3D space and a second virtual-experience server to simulate a second zone of the virtual 3D space. At least one subzone of the second zone shares a boundary in the virtual 3D space with the first zone. The first virtual-experience server simulates a first frame of the first zone by running at least one first virtual-experience model using previous state information associated with a previous frame of the first zone. The second virtual-experience server simulates another first frame of the second zone by running at least one second virtual-experience model using other previous state information associated with another previous frame of the second zone. The operations include, in response to the first frame and the another first frame corresponding to a first checkpoint interval, receiving, by the processor, first state information associated with the first frame from the first virtual-experience server and other first state information associated with the another first frame from the second virtual-experience server. The operations include, in response to the first frame and the another first frame corresponding to a first checkpoint interval, includes storing, by the processor, the first state information and the other first state information. The operations include, in response to a failure of the second virtual-experience server before simulation of another second frame of the second zone, causing, by the processor, the first virtual-experience server to perform recovery simulation for the at least one subzone of the second zone based on the other first state information. The first virtual-experience server performs the recovery simulation by running the at least one second virtual-experience model using a portion of the other first state information corresponding to the at least one subzone.

In some implementations, by causing the first virtual-experience server to perform the recovery simulation for the at least one subzone of the second zone that shares the boundary with the first zone, no inter-zone messages associated with objects in the first zone and the at least one subzone of the second zone and used for simulation are sent over a network during simulation of the first zone and the at least one subzone after the recovery simulation.

In some implementations, each zone of the virtual 3D space includes a respective plurality of subzones. In some implementations, each subzone includes at least one region associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

In some implementations, the operations include receiving, by the processor, at least one inter-zone message associated with at least one object located in the second zone from a third virtual-experience server. In some implementations, the operations include storing, by the processor, the at least one inter-zone message until a subsequent checkpoint interval. In some implementations, causing the first virtual-experience server to perform the recovery simulation for the at least one subzone of the second zone includes sending, by the processor, the other first state information and the at least one inter-zone message to first virtual-experience server. In some implementations, the first virtual-experience server performs the recovery simulation of the another second frame of the second zone by running the at least one second virtual-experience model using the portion of the other first state information and the at least one inter-zone message.

In some implementations, causing the first virtual-experience server to perform the recovery simulation for the at least one subzone of the second zone includes determining, by the processor, the at least one subzone of the second zone shares the boundary with the first zone in the virtual 3D space. In some implementations, causing the first virtual-experience server to perform the recovery simulation for the at least one subzone of the second zone includes determining, by the processor, the first zone is assigned to the first virtual-experience server based on a registry that indicates assignments of virtual-experience servers to zones of the virtual 3D space. In some implementations, causing the first virtual-experience server to perform the recovery simulation for the at least one subzone of the second zone includes determining, by the processor, a first available workload capacity of the first virtual-experience server based on its simulation of the first zone. In some implementations, causing the first virtual-experience server to perform the recovery simulation for the at least one subzone of the second zone includes determining, by the processor, a maximum number of first contiguous subzones of the second zone that includes the at least one subzone. In some implementations, a first collective workload of the first contiguous subzones does not exceed the first available workload capacity of the first virtual-experience server. In some implementations, causing the first virtual-experience server to perform the recovery simulation for the at least one subzone of the second zone includes causing, by the processor, the first virtual-experience server to perform the recovery simulation for the maximum number of first contiguous subzones of the second zone.

In some implementations, the operations include causing, by the processor, a third virtual-experience server to simulate a third zone of the virtual 3D space. In some implementations, the operations include, in response to the failure of the second virtual-experience server before the simulation of another second frame of the second zone, causing, by the processor, the third virtual-experience server to perform recovery simulation for at least one other subzone of the second zone based on the other first state information. In some implementations, the third virtual-experience server performs the recovery simulation of the another second frame of the second zone by running the at least one second virtual-experience model using another portion of the other first state information corresponding to the at least one other subzone. In some implementations, the at least one other subzone of the second zone shares a boundary with the third zone in the virtual 3D space.

In some implementations, causing the third virtual-experience server to simulate the third zone of the virtual 3D space includes determining, by the processor, the at least one other subzone of the second zone shares the boundary with the third zone, the at least one other subzone being excluded from the maximum number of first contiguous subzones. In some implementations, causing the third virtual-experience server to simulate the third zone of the virtual 3D space includes determining, by the processor, the third zone is assigned to the third virtual-experience server based on the registry that indicates assignments of virtual-experience servers to zones of the virtual 3D space. In some implementations, causing the third virtual-experience server to simulate the third zone of the virtual 3D space includes determining, by the processor, a second available workload capacity of the third virtual-experience server. In some implementations, causing the third virtual-experience server to simulate the third zone of the virtual 3D space includes determining, by the processor, a maximum number of second contiguous subzones of the second zone that includes the at least one other subzone. In some implementations, a second collective workload of the second contiguous subzones does not exceed the second available workload capacity of the third virtual-experience server. In some implementations, causing the third virtual-experience server to simulate the third zone of the virtual 3D space includes causing, by the processor, the third virtual-experience server to perform the recovery simulation for the maximum number of second contiguous subzones of the second zone.

In some implementations, the operations include determining, by the processor, a recovery of the second virtual-experience server. In some implementations, the operations include, in response to the recovery of the second virtual-experience server, causing, by the processor, the second virtual-experience server to simulate the second zone of the virtual 3D space.

In some implementations, the operations include, after the first virtual-experience server performs the recovery simulation, determining, by the processor, a reduction in a workload capacity of the first virtual-experience server. In some implementations, the operations include, in response to the reduction in the workload capacity of the first virtual-experience server, causing, by the processor, a third virtual-experience server to simulate the at least one subzone of the second zone or at least one other subzone of the first zone.

In some implementations, the operations include receiving, by the processor, an indication of acceptance of the at least one subzone of the second zone for simulation from the first virtual-experience server. In some implementations, the operations include, in response to receiving the indication, sending, by the processor, a list of at least one other virtual-experience server that stores replicated state information for the at least one subzone of the second zone to the first virtual-experience server.

In some implementations, the operations include selecting, by the processor, a number of subzones per zone based on one or more of a target speed of simulation recovery or a number of frames associated with each checkpoint interval.

According to another aspect of the present disclosure, a non-transitory computer-readable medium storing instructions for a first virtual-experience server is provided. The instructions, which when executed by a processor of the first virtual-experience server, cause the processor of the first virtual-experience server to perform operations. The operations include simulating, by a processor, a first frame of a first zone of a virtual 3Dspace by running at least one first virtual-experience model using previous state information associated with a previous frame of the first zone. The operations include, in response to the first frame corresponding to a first checkpoint interval, sending, by the processor, first state information associated with the first frame to a coordinator node. The operations include, in response to a failure of a second virtual-experience server before simulation of another first frame of a second zone, receiving, by the processor, a reassignment of at least one subzone of the second zone for simulation from the coordinator node. The at least one subzone shares a boundary with the first zone in the virtual 3D space. The operations include, in response to a failure of a second virtual-experience server before simulation of another first frame of a second zone, receiving, by the processor, other previous state information associated with another previous frame of the second zone from the coordinator node. The operations include, in response to a failure of a second virtual-experience server before simulation of another first frame of a second zone, performing, by the processor, a recovery simulation of the another first frame of the second zone by running a second virtual-experience model using a portion of the other previous state information corresponding to the at least one subzone.

In some implementations, by receiving the reassignment of the at least one subzone of the second zone that shares a boundary with the first zone, no inter-zone messages associated with objects in the first zone and the at least one subzone of the second zone and used for simulation are sent over a network during a subsequent simulation of the first zone and the at least one subzone.

In some implementations, each zone of the virtual 3D space comprises a plurality of subzones. In some implementations, each subzone comprises at least one region associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

In some implementations, the operations include, in response to the failure of the second virtual-experience server before simulation of the another first frame of the second zone, receiving, by the processor, at least one inter-zone message associated with at least one object located in the second zone from the coordinator node. In some implementations, performing the recovery simulation of the another first frame of the at least one subzone of the second zone includes simulating, by the processor, the another first frame of the at least one subzone of the second zone by running the second virtual-experience model using the portion of the other previous state information and the at least one inter-zone message.

In some implementations, the operations include, in response to a recovery of the second virtual-experience server, sending, by the processor, current state information associated with the at least one subzone of the second zone to one or more of the second virtual-experience server or the coordinator node.

In some implementations, the operations include, after performing the recovery simulation, determining, by the processor, a reduction in a workload capacity. In some implementations, the operations include, in response to the reduction in the workload capacity, sending a request to the coordinator node, by the processor, for a reassignment of one or more of subzones of the first zone or the second zone to another virtual-experience server.

In some implementations, the operations include sending, by the processor, an indication accepting the at least one subzone of the second zone for simulation to the coordinator node. In some implementations, the operations include receiving, by the processor and from the coordinator node, a list of at least one other virtual-experience server that stores replicated state information for the at least one subzone of the second zone from the coordinator node. In some implementations, the operations include sending, by the processor, the replicated state information for the at least one subzone of the second zone to the at least one other virtual-experience server.

According to a further aspect of the present disclosure, a non-transitory computer-readable medium storing instructions for a client device is provided. The instructions, which when executed by a processor of the client device, cause the processor of the client device to perform operations. The operations include simulating, by a processor, a first frame of a first zone of a virtual 3D space by running at least one first virtual-experience model using previous state information associated with a previous frame of the first zone. The operations include, in response to a failure of a first virtual-experience server associated with the first zone, receiving, by the processor, an indication that a first subzone of the first zone is reassigned to a second virtual-experience server and a second subzone of the first zone is reassigned to a third virtual-experience server from a coordinator node. The operations include, in response to a failure of a first virtual-experience server associated with the first zone, sending, by the processor, first state information associated with the first frame of the first zone to the second virtual-experience server and the third virtual-experience server. The second virtual-experience server is assigned a first subzone of the first zone that shares a boundary with a second zone simulated by the second virtual-experience server. The third virtual-experience server is assigned a second subzone of the first zone that shares a boundary with a third zone simulated by the third virtual-experience server.

In some implementations, each zone of the virtual 3D space includes a plurality of subzones. In some implementations, each subzone comprises at least one region associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

According to still another aspect of the present disclosure, a non-transitory computer-readable medium storing instructions for a coordinator node is provided. The instructions, which when executed by the processor of the coordinator node, cause the processor of the coordinator node to perform operations. The operations include causing, by a processor, a first virtual-experience server to simulate a first region of a virtual 3D space and a second virtual-experience server to simulate a second region of the virtual 3D space. The first virtual-experience server simulates a first frame of the first region by running at least one first virtual-experience model using previous state information associated with a previous frame of the first region. The second virtual-experience server simulates another first frame of the second region by running at least one second virtual-experience model using other previous state information associated with another previous frame of the second region. The operations include, in response to the first frame and the another first frame corresponding to a first checkpoint interval, receiving, by the processor, first state information associated with the first frame from the first virtual-experience server and other first state information associated with the another first frame from the second virtual-experience server. The operations include, in response to the first frame and the another first frame corresponding to a first checkpoint interval, storing, by the processor, the first state information and the other first state information. The operations include, in response to a failure of the second virtual-experience server before simulation of another second frame of the second region, causing, by the processor, the first virtual-experience server to perform recovery simulation for the second region based on the other first state information. The first virtual-experience server performs the recovery simulation by running the at least one second virtual-experience model using the other first state information.

In some implementations, each region is associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

In some implementations, the operations include receiving, by the processor, at least one inter-zone message associated with at least one object located in the second region from a third virtual-experience server. In some implementations, the operations include storing, by the processor, the at least one inter-zone message until a subsequent checkpoint interval.

In some implementations, causing the first virtual-experience server to perform the recovery simulation for the second region includes sending, by the processor, the other first state information and the at least one inter-zone message to first virtual-experience server. In some implementations, causing the first virtual-experience server to perform the recovery simulation for the second region includes causing, by the processor, the first virtual-experience server to perform recovery simulation for the second region based on the other first state information and the at least one inter-zone message. In some implementations, the first virtual-experience server performs the recovery simulation by running the at least one second virtual-experience model using the other first state information and the at least one inter-zone message.

In some implementations, the operations include in response to receiving the first state information and the other first state information, deleting, by the processor, the previous state information and the other previous state information. In some implementations, the previous state information and the other previous state information are associated with a previous checkpoint interval.

In some implementations, the operations include receiving, by the processor, an indication of acceptance of the second region for simulation from the first virtual-experience server. In some implementations, the operations include, in response to receiving the indication, sending, by the processor, a list of at least one other virtual-experience server that stores replicated state information for the second region of the virtual 3D space to the first virtual-experience server.

In some implementations, the operations include, in response to the failure of the second virtual-experience server, sending, by the processor, an indication that the second region of the virtual 3D space is reassigned to the first virtual-experience server to at least one client device simulating the second region.

In some implementations, the coordinator node includes one or more virtual 3D space servers. In some implementations, the coordinator node includes one or more storage devices.

According to still a further aspect of the present disclosure, a non-transitory computer-readable medium storing instructions for a virtual-experience server is provided. The instructions, which when executed by a processor of the virtual-experience server, cause the processor of the virtual-experience server to perform operations. The operations include simulating, by a processor, a first frame of a first region of a virtual 3D space by running at least one first virtual-experience model using previous state information associated with a previous frame of the first region. The operations include, in response to the first frame corresponding to a first checkpoint interval, sending, by the processor, first state information associated with the first frame to a coordinator node. The operations include, in response to a failure of a second virtual-experience server before simulation of another first frame of a second region, receiving, by the processor, a reassignment of the second region for simulation from the coordinator node. The operations include, in response to a failure of a second virtual-experience server before simulation of another first frame of a second region, receiving, by the processor, other previous state information associated with another previous frame of the second region from the coordinator node. The operations include, in response to a failure of a second virtual-experience server before simulation of another first frame of a second region, performing, by the processor, a recovery simulation of the second region by running a second virtual-experience model using the other previous state information.

In some implementations, each region of the virtual 3D space is associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

In some implementations, the operations include, in response to the failure of the second virtual-experience server before simulation of the another first frame of the second region, receiving, by the processor, at least one inter-region message associated with at least one object located in the second region from the coordinator node. In some implementations, performing the recovery simulation of the second region includes simulating, by the processor, the another first frame of the second region by running the second virtual-experience model using the other previous state information and the at least one inter-region message.

In some implementations, the operations include, in response to a recovery of the second virtual-experience server, sending, by the processor, current state information associated with the second region to one or more of the second virtual-experience server or the coordinator node.

In some implementations, the operations include, after performing the recovery simulation, determining, by the processor, a reduction in a workload capacity. In some implementations, the operations include, in response to the reduction in the workload capacity, requesting, by the processor, a reassignment of one or more of the first region or the second region to another virtual-experience server.

In some implementations, the operations include sending, by the processor, an indication of acceptance of the second region for simulation to the coordinator node. In some implementations, the operations include, in response to the coordinator node receiving the indication, receiving, by the processor, a list of at least one other virtual-experience server that stores replicated state information for the second region from the coordinator node. In some implementations, the operations include sending, by the processor, the replicated state information for the second region to the at least one other virtual-experience server.

According to yet another aspect of the present disclosure, a non-transitory computer-readable medium storing instructions for a client device is provided. The instructions, which when executed by a processor of the client device, cause the processor of the client device to perform operations. The operations include simulating, by a processor, a first frame of a first region of a virtual 3D space by running at least one first virtual-experience model using previous state information associated with a previous frame of the first region. The operations include, in response to a failure of a first virtual-experience server associated with the first region, receiving, by the processor, an indication that the first region is reassigned to a second virtual-experience server. The operations include, in response to a failure of a first virtual-experience server associated with the first region, sending, by the processor, first state information associated with the first frame of the first region to the second virtual-experience server.

In some implementations, each region is associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

According to yet another aspect, portions, features, and implementation details of the systems, methods, and non-transitory computer-readable media may be combined to form additional aspects, including some aspects which omit and/or modify some or portions of individual components or features, include additional components or features, and/or other modifications; and all such modifications are within the scope of this disclosure.

### BRIEF DESCRIPTION OF DRAWINGS

FIG. 1 is a diagram of an example network environment, in accordance with some implementations.

FIG. 2 illustrates example regions of a virtual space, in accordance with some implementations.

FIGS. 3A-3E are a call flow diagram illustrating first example operations for simulation recovery, in accordance with some implementations.

FIG. 4 is a diagram illustrating example zones of a virtual space, in accordance with some implementations.

FIGS. 5A-5G are a call flow diagram illustrating second example operations for simulation recovery, in accordance with some implementations.

FIGS. 6A and 6B are a flowchart of a first example method for simulation recovery by a coordinator node, in accordance with some implementations.

FIGS. 7A and 7B are a flowchart of a first example method for simulation recovery by a virtual-experience server, in accordance with some implementations.

FIG. 8 is a flowchart of a first example method for simulation recovery by a client device, in accordance with some implementations.

FIGS. 9A-9C are a flowchart of a second example method for simulation recovery by a coordinator node, in accordance with some implementations.

FIGS. 10A and 10B are a flowchart of a second example method for simulation recovery by a virtual-experience server, in accordance with some implementations.

FIG. 11 is a flowchart of a second example method for simulation recovery by a client device, in accordance with some implementations.

FIG. 12 is a block diagram illustrating an example computing device, in accordance with some implementations.

### DETAILED DESCRIPTION

In the following detailed description, reference is made to the accompanying drawings, which form a part hereof. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented herein. Aspects of the present disclosure, as generally described herein, and illustrated in the Figures, can be arranged, substituted, combined, separated, and designed in a wide variety of different configurations, all of which are contemplated herein.

References in the specification to “some implementations”, “an implementation”, “an example implementation”, etc. indicate that the implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, such feature, structure, or characteristic may be effected in connection with other implementations whether or not explicitly described.

Various embodiments are described herein in the context of three-dimensional (3D) avatars that are used in a 3D virtual experience or environment. Some implementations of the techniques described herein may be applied to various types of 3D environments, such as a virtual reality (VR) conference, a 3D session (e.g., an online lecture or other type of presentation involving 3D avatars), a virtual concert, an augmented reality (AR) session, or in other types of 3D environments that may include one or more users that are represented in the 3D environment by one or more 3D avatars.

Virtual-experience platforms typically include two types of nodes: client devices and virtual-experience servers. Client devices belong to individual users and display a view of the virtual experience that the user can interact with, while virtual-experience servers manage the state of the virtual experience and coordinate simulation. Due to the central role of virtual-experience servers, the simulation cannot proceed without them and is terminated if a virtual-experience server fails. To recover from this type of simulation failure, existing solutions add redundancy by maintaining copies or replicas of the state of the virtual experience on other virtual-experience servers, which then take over the simulation when a failure occurs.

However, this solution requires many additional virtual-experience servers to maintain replicas. For instance, for a simulation to survive a failure of up to f virtual-experience servers, the number of virtual-experience servers storing replicas is increased by a factor of f+1. In other words, for each of the original virtual-experience servers, f additional virtual-experience servers maintain a replica to ensure that at least one of them survives a network failure. This increases the overall cost of building and maintaining the network. Moreover, the vast majority of information included in the replicas is associated with simulated frames that are too old to be useful in the simulation recovery for a current frame, thereby introducing unnecessary signaling overhead.

Thus, there is an unmet need for a simulation-recovery technique that uses fewer virtual-experience servers and limits the amount of signaling overhead.

To overcome these and other challenges, the present disclosure provides a vault-streaming recovery technique and topology-aware recovery technique, both of which may be implemented based on the following insights.

First, virtual-experience workloads have strict real-time requirements and the state is updated periodically, e.g., such as several times per second. However, it may be acceptable to briefly delay these updates in the event of a virtual-experience server failure. For instance, these updates may be delayed by a few milliseconds. Because of this, the present techniques achieve simulation recovery by masking a simulation failure.

To mask and recover from a simulation failure, the state information that was stored on the faulty virtual-experience server(s) may be used. This may be accomplished by maintaining replicas of the state on other virtual-experience servers. However, the undesirable cost of maintaining full replicas can be avoided by storing only the information that is necessary to reconstruct the state when a failure of a virtual-experience server occurs.

The inherent parallelism of virtual experiences provides another option, however; namely, the computational workload of simulation recovery may be spread across multiple virtual-experience servers.

An example computational workload may include, e.g., 1) a physics simulation and 2) the execution of scripts. Moreover, it is assumed that the simulation proceeds in discrete frames. In other words, the state of frame i+1 is computed by running the physics simulation and the scripts on the state of frame i. The physics simulation is performed on physics islands, which include individual objects plus any objects with which they are in physical contact or are otherwise connected. The physics simulation and the script execution are deterministic; that is, if these virtual-experience models are run multiple times starting from identical frame states, they will compute approximately the same next frame states.

This type of computational workload exhibits strong spatial locality because the computation mostly involves the state of objects that are proximate to one another within the virtual space. The only exception are the messages that the scripts send and receive; these do not need to be local and can be exchanged between any pair of scripts, which may be managed by different virtual-experience servers. For instance, if an avatar interacts with a trap door in a first area of the virtual space, another trap door in a second area not visible to the avatar may open. Assuming, the first area of the virtual space is managed by a first virtual-experience server and the second area is managed by a second virtual-experience server, the first virtual-experience server will send a script message to the second virtual-experience server.

An object may be defined as any contiguous, self-contained entity (e.g., an avatar, a car, a chair, etc.) in the virtual space. Objects can be stationary or mobile, and they may be formed of multiple parts and various kinds of connections or constraints. Scripts are programs that encode game logic; for the purposes of the present disclosure, it is assumed that each script is associated with an object and can interact with that object or exchange messages with other scripts.

The present techniques divide the virtual space into a plurality of contiguous spatial regions, each containing the objects and scripts in that region. Each region is assumed to be large enough that each physics island is either contained entirely within a region or spans only regions that are adjacent to each other.

The simulation of a region is managed by a dedicated virtual-experience server. Each virtual-experience server also contains a replica of any region that is adjacent to the region managed by that virtual-experience server. A registry is used to map corresponding regions and objects to their respective virtual-experience servers. The state of the registry may be derived from the state information stored at the virtual-experience servers and can be rebuilt by having each virtual-experience server report which regions and objects it contains.

Each virtual-experience server computes the state of frame i+1 of its corresponding region according to the following. For instance, a virtual-experience server may apply the inputs received from client devices (e.g., key presses) that affect the velocity or orientation of a user’s avatar or cause the avatar to interact with other objects in the region. The physics simulation is completed for objects in the region(s) for which the virtual-experience server maintains the primary copy. This is possible because physics islands can at most extend into adjacent regions, and the virtual-experience server maintains a replica of these adjacent regions.

The scripts are executed for any region for which the virtual-experience server maintains the primary copy. A script may be executed by first receiving any incoming inter-region messages associated with the previous frame and then executing each script based on the state information of the previous frame and the inter-region messages. This is possible because the scripts can only directly interact with their corresponding objects, which would be in the same region associated with the script. If the scripts have inter-region messages to send, the virtual-experience server may use the registry to look up the corresponding server(s) that have copies (primary or replica) of the destination objects and transmit the messages to these servers or to a coordinator node. An inter-region message may be generated when an avatar in one region performs an action that affects an object in another region.

If a virtual-experience server’s region(s) include objects that move to another region, the virtual-experience server may serialize these objects and delete them from the current region. The virtual-experience server may identify from the registry the region into which the object moves. Then, the object and any corresponding state information may be sent to the virtual-experience server(s) that manage the region into which the object moves. Replicated state information may be updated at predetermined intervals, where each virtual-experience server sends any updated state information to other virtual-experience server(s) that maintain a replicated copy for that region.

Each client device uses one of the objects as its avatar. A client device may perform normal interest management using the registry to look up the avatar’s location in the virtual space, as well as nearby regions that are visible from the avatar’s location. The client device may establish a connection with these server(s) to receive state information updates for these regions. The client device forwards any user inputs as definitive state information to the virtual-experience server(s) that have copies of the relevant regions. These inputs are tagged with a specific frame number, so they can be applied consistently.

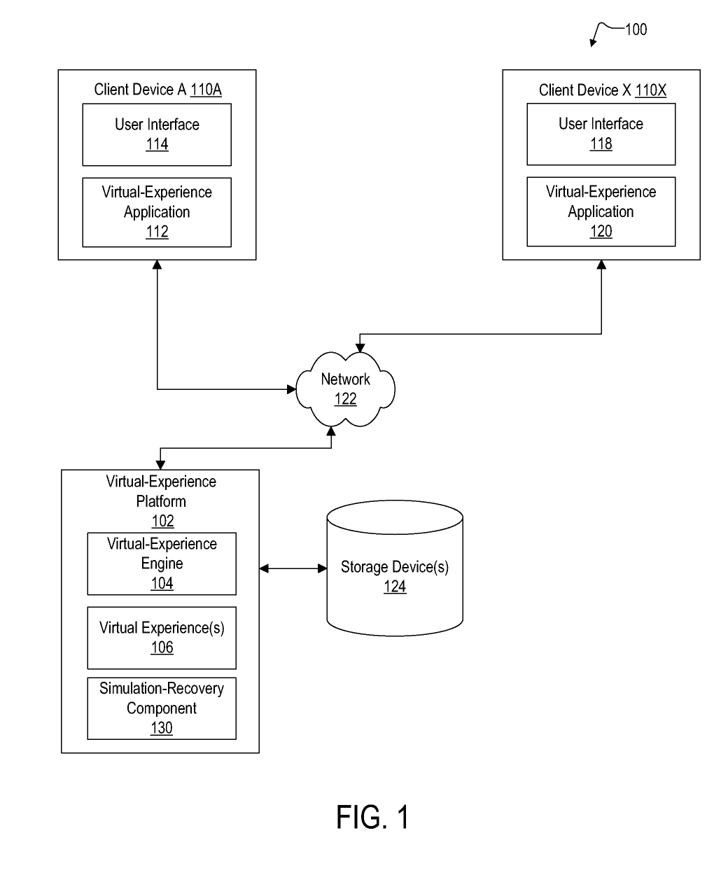

The present techniques achieve recovery simulation with a limited number of virtual-experience servers and a limited amount of network overhead. Additional details of the present techniques are provided below with reference to FIGS. 1-12.

### FIG. 1: System architecture

FIG. 1 illustrates an example network environment 100, in accordance with some implementations of the disclosure. FIG. 1 and the other figures use like reference numerals to identify like elements. A letter after a reference numeral, such as “110a,” indicates that the text refers specifically to the element having that particular reference numeral. A reference numeral in the text without a following letter, such as “110,” refers to any or all of the elements in the figures bearing that reference numeral (e.g., “110” in the text refers to reference numerals “110a,” “110b,” and/or “110n” in the figures).

The network environment 100 (also referred to as a “platform” herein) includes an online virtual experience server 102, a data store 108, a client device 110 (or multiple client devices), and a third-party server 118, all connected via a network 122.

The online virtual experience server 102 can include, among other things, a virtual experience engine 104, one or more virtual experiences 105, and simulation-recovery component 130. The online virtual experience server 102 may be configured to provide virtual experiences 105 to one or more client devices 110, and to store state information (either primary or replicas) for one or more regions via the simulation-recovery component 130, in some implementations.

Data store 108 is shown coupled to online virtual experience server 102 but in some implementations, can also be provided as part of the online virtual experience server 102. The data store may, in some implementations, be configured to store advertising data, user data, engagement data, and/or other contextual data in association with the simulation-recovery component 130.

The client devices 110 (e.g., 110a, 110b, 110n) can include a virtual experience application 112 (e.g., 112a, 112b, 112n) and an I/O interface 114 (e.g., 114a, 114b, 114n), to interact with the online virtual experience server 102, and to view, for example, graphical user interfaces (GUI) through a computer monitor or display (not illustrated). In some implementations, the client devices 110 may be configured to execute and display virtual experiences, which may include virtual user engagement portals as described herein.

Network environment 100 is provided for illustration. In some implementations, the network environment 100 may include the same, fewer, more, or different elements configured in the same or different manner as that shown in FIG. 1.

In some implementations, network 122 may include a public network (e.g., the Internet), a private network (e.g., a local area network (LAN) or wide area network (WAN)), a wired network (e.g., Ethernet network), a wireless network (e.g., an 1002.11 network, a Wi-Fi® network, or wireless LAN (WLAN)), a cellular network (e.g., a Long Term Evolution (LTE) network), routers, hubs, switches, server computers, or a combination thereof.

In some implementations, the data store 108 may be a non-transitory computer readable memory (e.g., random access memory), a cache, a drive (e.g., a hard drive), a flash drive, a database system, or another type of component or device capable of storing data. The data store 108 may also include multiple storage components (e.g., multiple drives or multiple databases) that may also span multiple computing devices (e.g., multiple server computers).

In some implementations, the online virtual experience server 102 can include a server having one or more computing devices (e.g., a cloud computing system, a rackmount server, a server computer, cluster of physical servers, virtual server, etc.). In some implementations, a server may be included in the online virtual experience server 102, be an independent system, or be part of another system or platform. In some implementations, the online virtual experience server 102 may be a single server, or any combination of a plurality of servers, load balancers, network devices, and other components. The online virtual experience server 102 may also be implemented on physical servers, but may utilize virtualization technology, in some implementations. Other variations of the online virtual experience server 102 are also applicable.

In some implementations, the online virtual experience server 102 may include one or more computing devices (such as a rackmount server, a router computer, a server computer, a personal computer, a mainframe computer, a laptop computer, a tablet computer, a desktop computer, etc.), data stores (e.g., hard disks, memories, databases), networks, software components, and/or hardware components that may be used to perform operations on the online virtual experience server 102 and to provide a user (e.g., user via client device 110) with access to online virtual experience server 102.

The online virtual experience server 102 may also include a website (e.g., one or more web pages) or application back-end software that may be used to provide a user with access to content provided by online virtual experience server 102. For example, users (or developers) may access online virtual experience server 102 using the virtual experience application 112 on client device 110, respectively.

In some implementations, online virtual experience server 102 may include digital asset and digital virtual experience generation provisions. For example, the platform may provide administrator interfaces allowing the design, modification, unique tailoring for individuals, and other modification functions. In some implementations, virtual experiences may include two-dimensional (2D) games, three-dimensional (3D) games, virtual reality (VR) games, or augmented reality (AR) games, for example. In some implementations, virtual experience creators and/or developers may search for virtual experiences, combine portions of virtual experiences, tailor virtual experiences for particular activities (e.g., group virtual experiences), and other features provided through the online virtual experience server 102.

In some implementations, online virtual experience server 102 or client device 110 may include the virtual experience engine 104 or virtual experience application 112. In some implementations, virtual experience engine 104 may be used for the development or execution of virtual experiences 105. For example, virtual experience engine 104 may include a rendering engine (“renderer”) for two-dimensional (2D), three-dimensional (3D), virtual reality (VR), or augmented reality (AR) graphics, a physics engine, a collision detection engine (and collision response), sound engine, scripting functionality, haptics engine, artificial intelligence engine, networking functionality, streaming functionality, memory management functionality, threading functionality, scene graph functionality, or video support for cinematics, among other features. The components of the virtual experience engine 104 may generate commands that help compute and render the virtual experience (e.g., rendering commands, collision commands, physics commands, etc.).

The online virtual experience server 102 using virtual experience engine 104 may perform some or all the virtual experience engine functions (e.g., generate physics commands, rendering commands, etc.), or offload some or all the virtual experience engine functions to virtual experience engine 104 of client device 110 (not illustrated). In some implementations, each virtual experience 105 may have a different ratio between the virtual experience engine functions that are performed on the online virtual experience server 102 and the virtual experience engine functions that are performed on the client device 110.

In some implementations, virtual experience instructions may refer to instructions that allow a client device 110 to render gameplay, graphics, and other features of a virtual experience. The instructions may include one or more of user input (e.g., physical object positioning), character position and velocity information, or commands (e.g., physics commands, rendering commands, collision commands, etc.).

In some implementations, the client device(s) 110 may each include computing devices such as personal computers (PCs), mobile devices (e.g., laptops, mobile phones, smart phones, tablet computers, or netbook computers), network-connected televisions, gaming consoles, etc. In some implementations, a client device 110 may also be referred to as a “user device.” In some implementations, one or more client devices 110 may connect to the online virtual experience server 102 at any given moment. It may be noted that the number of client devices 110 is provided as illustration, rather than limitation. In some implementations, any number of client devices 110 may be used.

In some implementations, each client device 110 may include an instance of the virtual experience application 112. The virtual experience application 112 may be rendered for interaction at the client device 110. During user interaction within a virtual experience or another GUI of the network environment 100, definitive state information associated with one or more objects in the region may be generated. The simulation-recovery component 130 may use the definitive state information (e.g., from client device 110), state information from checkpoint intervals (e.g., from other servers), and any inter-region messages (e.g., from other servers) to enable simulation recovery.

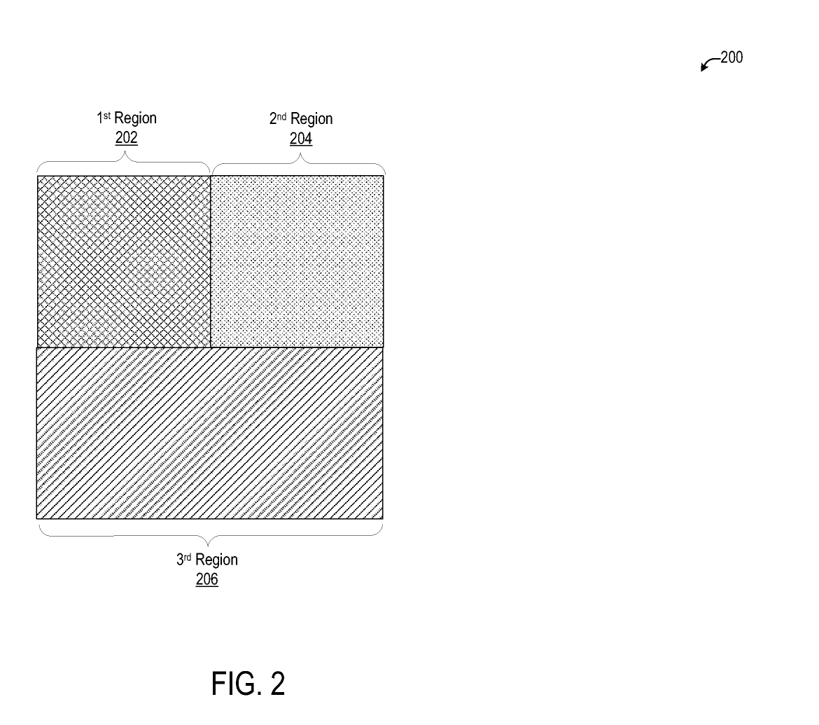

Hereinafter, a more detailed discussion of the simulation-recovery component 130 is presented with reference to FIGS. 2, 3A-3E, 4 and 5A-5G.

### FIG. 2: Example Regions of a Virtual Experience

FIG. 2 illustrates example regions of a virtual space 200, in accordance with some implementations.

In some implementations, to achieve simulation recovery, the present techniques divide a virtual space into a plurality of contiguous spatial regions, each containing spatially located objects and scripts. Each region is assumed to be large enough that each physics island is either contained entirely therein or spans only regions that are adjacent.

In the non-limiting example shown in FIG. 2, the virtual space 200 is divided into a first region 202, a second region 204, and a third region 206. However, the virtual space 200 may include more or fewer than three regions. Moreover, the size and shape of each region may be the same or different.

The simulation of an individual region of the virtual space 200 is managed by a dedicated virtual-experience server (not shown). Each virtual-experience server also contains a replica of any region that is adjacent to the region managed by that virtual-experience server. For instance, referring to FIG. 2, the first region 202 may be managed by a first virtual-experience server, the second region 204 may be managed by a second virtual-experience server, the third region 206 may be managed by a third virtual-experience server, and so on.

A coordinator node (not shown) maintains a registry that maps corresponding regions and objects to their respective virtual-experience servers. The state of the registry may be derived from the state information stored at the virtual-experience servers and can be rebuilt by having each virtual-experience server report which regions and objects it contains.

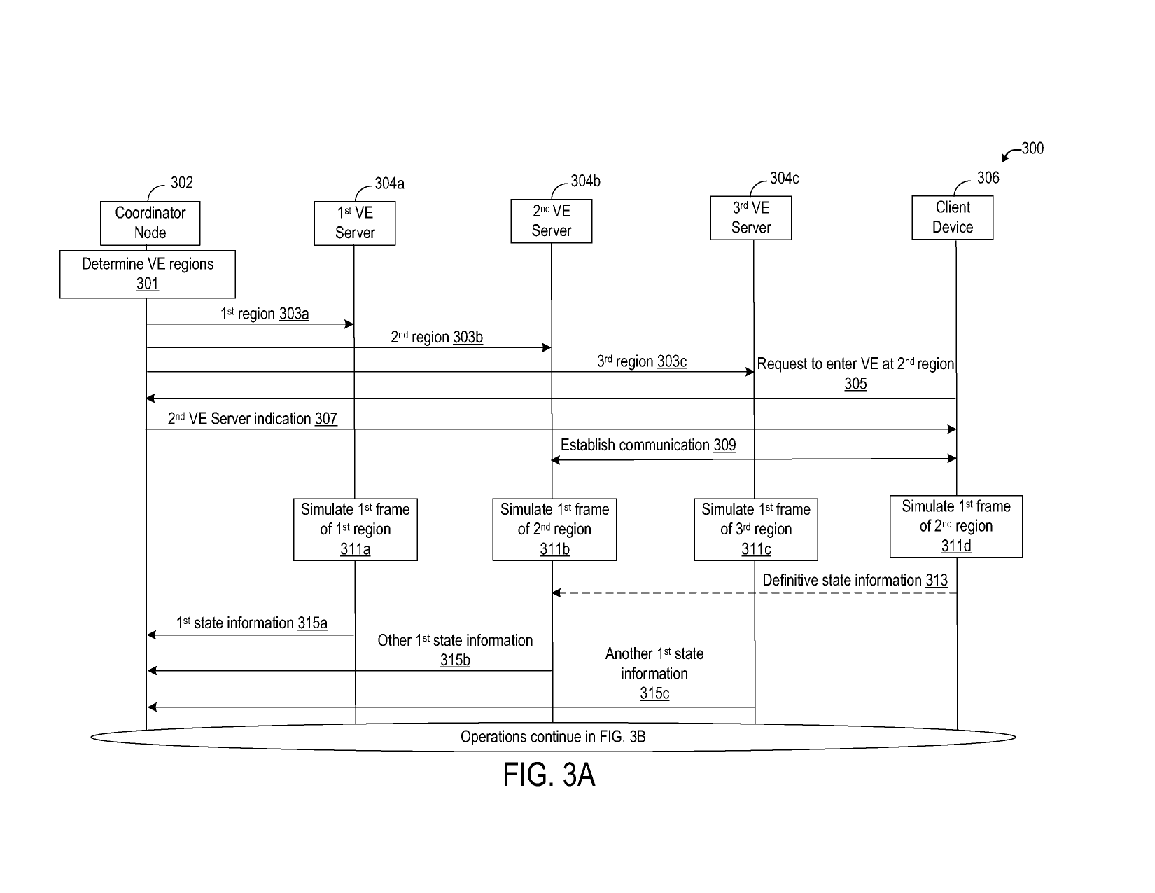

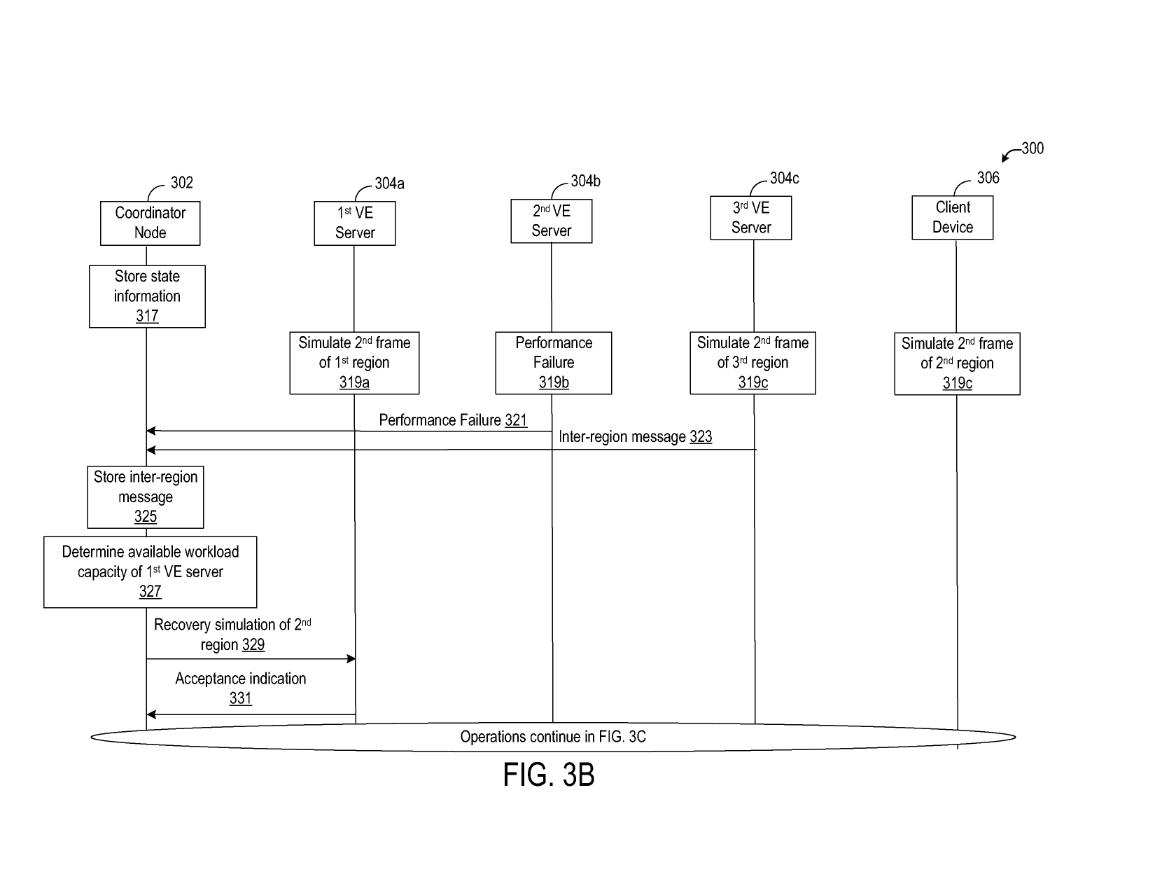

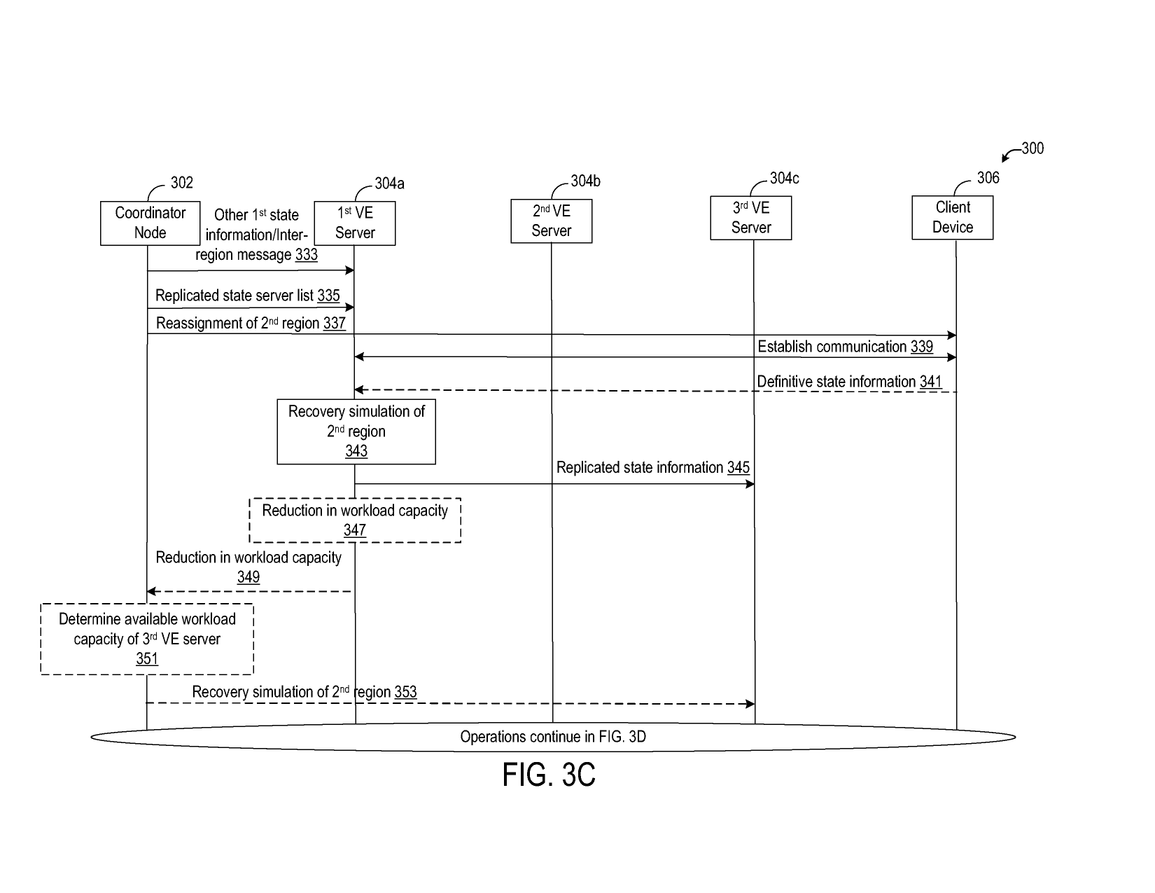

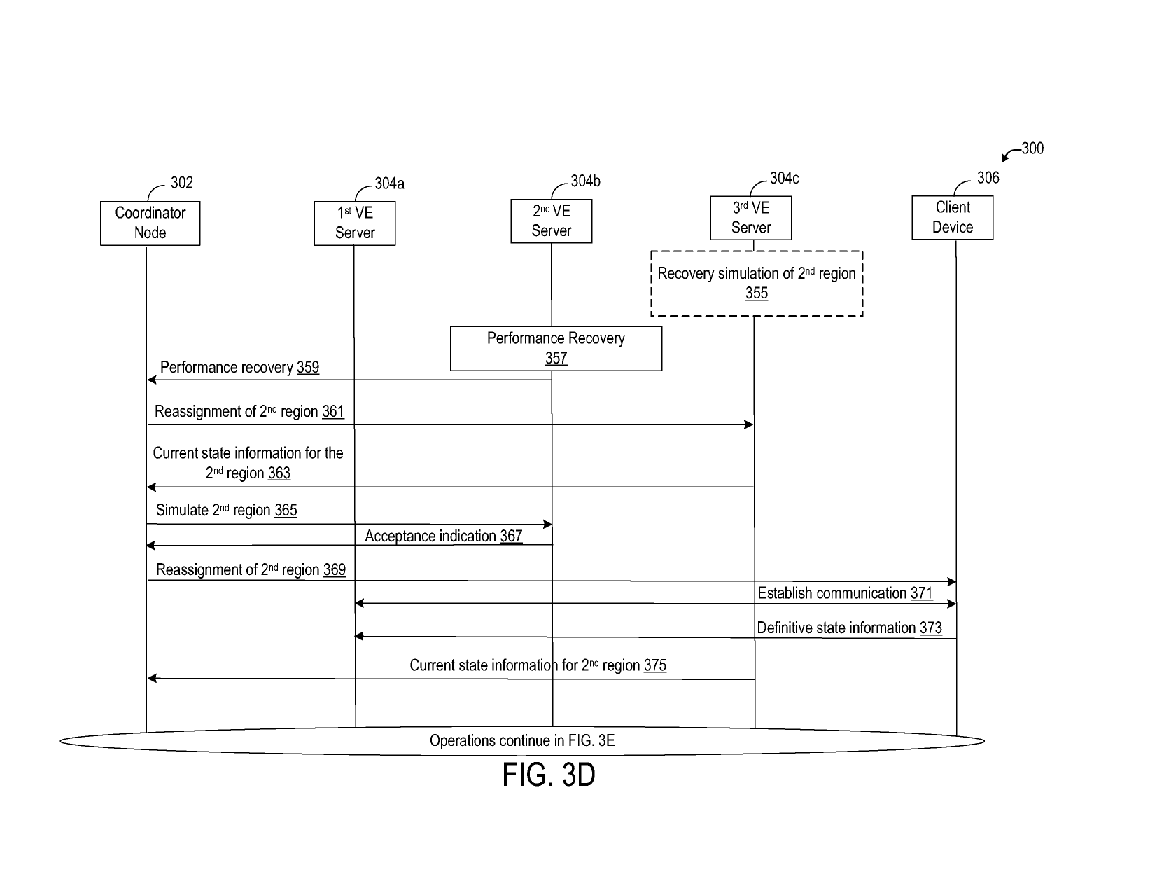

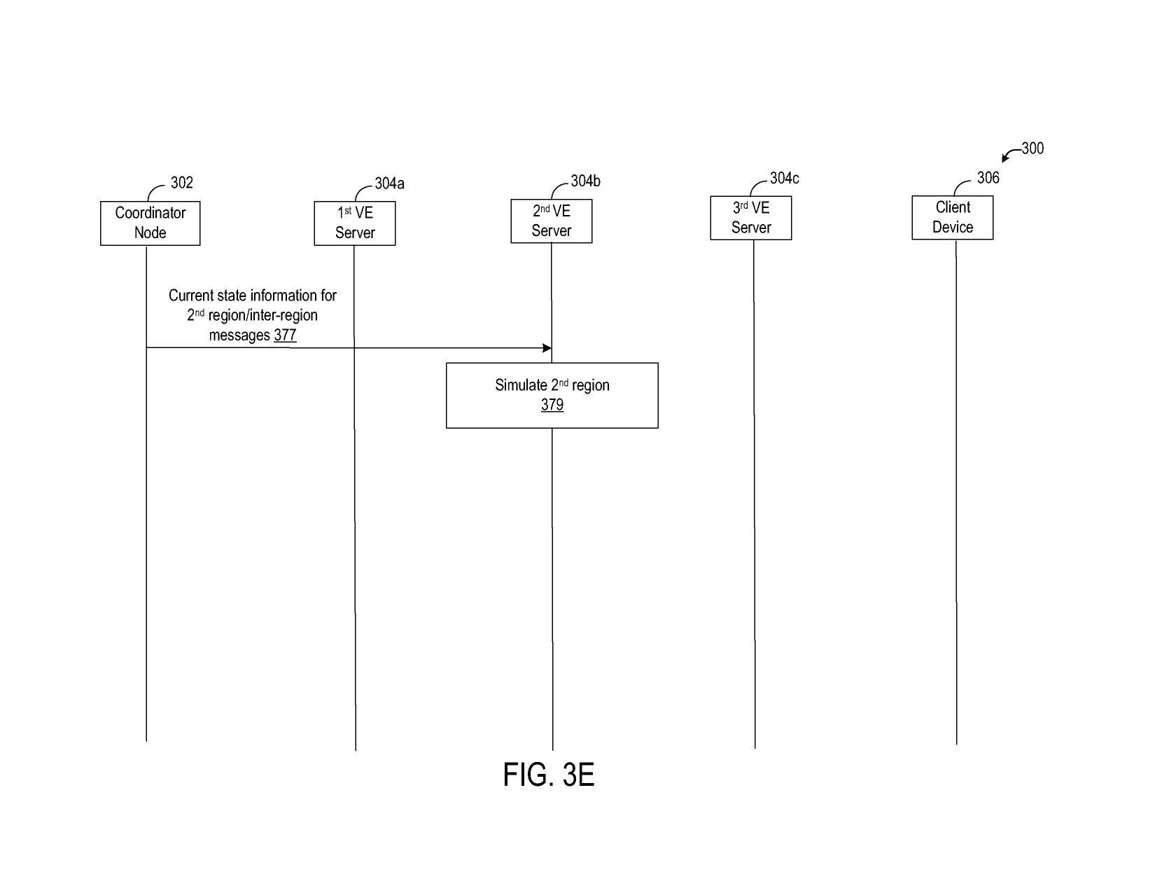

In the event of virtual-experience server failure, vault-streaming recovery may be performed according to the operations described below with reference to FIGS. 3A-3E.

### FIGS. 3A-3E: Example Call Flow Diagram for Vault-Streaming Recovery

FIGS. 3A-3E are a call flow diagram illustrating first example operations 300 for simulation recovery, in accordance with some implementations. As shown in FIGS. 3A-3E, the example operations may be performed by, e.g., a coordinator node 302, a first virtual-experience server 304a, a second virtual-experience server 304b, a third virtual-experience server 304c, and a client device 306. The coordinator node 302 may be configured as one or more servers and/or a central set of machines in a data center. It is understood that more or fewer virtual-experience servers and client devices may be associated with the virtual experience than those depicted in FIGS. 3A-3E. Optional operations may be indicated with dashed lines in FIGS. 3A-3E.

Referring to FIG. 3A, the coordinator node 302 determines (at 301) the number of regions of the virtual experience. For example, coordinator node 302 may divide the virtual space into a plurality of contiguous spatial regions, each containing spatially located objects. Each region is determined so that each physics island is either contained entirely within a region or only spans adjacent regions. Each physics island is formed by one or more connected objects and at least one corresponding virtual-experience script associated with the one or more connected objects. In other words, the coordinator node 302 may divide the virtual space into regions so that the computational workload associated with simulating the one or more connected objects is associated with spatial locality.

In the non-limiting example of FIG. 3A, the coordinator node 302 may determine three regions of the virtual world and assign each of the three regions to a respective virtual-experience server. For example, the coordinator node 302 may assign (at 303a) the first region to the first virtual-experience server 304a, assign (at 303b) the second region to the second virtual-experience server 304b, and assign (at 303c) the third region to the third virtual-experience server 304c.

The coordinator node 302 may maintain a registry that maps corresponding regions and objects to their respective virtual-experience servers. As mentioned above, the state of the registry may be derived from the state information stored at the virtual-experience servers and can be rebuilt by having each virtual-experience server report which regions and objects it contains.

The client device 306 may request (at 305) to enter the virtual experience in the second region, for example. For instance, the second region may be the starting location of the virtual experience. Upon receipt of the request, the coordinator node 302 may access the registry and determine the second region is currently managed by the second virtual-experience server 304b. The coordinator node 302 may send (at 307) a message to the client device 306, indicating that the second virtual-experience server 304b manages the second region. The client device 306 may establish (at 309) communication with the second virtual-experience server 304b, which enables the user to interact with the virtual experience.

At a time period corresponding to a first frame of the simulated virtual experience, the first virtual-experience server 304a may simulate (at 311a) a first frame of the first region, the second virtual-experience server 304b may simulate (at 311b) a first frame of the second region, the third virtual-experience server 304c may simulate (at 311c) a first frame of the third region, and the client device 306 may simulate (at 311d) a first frame of the second region.

Each virtual-experience server simulates the frame i+1 of its corresponding region according to the following. For instance, the second virtual-experience server 304b may apply the inputs received from the client device 306 (e.g., key presses) that would affect the velocity or orientation of a user’s avatar. The physics simulation is completed for objects in the second region for which the second virtual-experience server 304b maintains the primary copy.

Still using the second region as an example, the second virtual-experience server 304b may further simulate the first frame by executing scripts for the second region. A script may be executed by receiving any incoming inter-region messages associated with the previous frame and executing each script based on the state information of the previous frame and the inter-region messages. If the scripts have inter-zone messages to send, the second virtual-experience server 304b may use the registry to look up the corresponding server(s) that have copies (primary or replica) of the destination objects and transmit the messages to these servers. An inter-region message may be generated when an avatar in one region performs an action that affects an object in another region. In some implementations, the second virtual-experience server 304b may maintain a copy of the registry, which it access directly. In some other implementations, the second virtual-experience server 304b may access the registry via the coordinator node 302.

Still referring to FIG. 3A, the client device 306 may send (at 313) definitive state information associated with its avatar’s actions in the second region to the second virtual-experience server 304b. The second virtual-experience server 304b may generate or update the state information it maintains for the second region based at least in part on the definitive state information received from the client device 306.

In response to the first frame being associated with a first checkpoint interval, the first virtual-experience server sends (at 315a) first state information associated with the first frame of the first region to the coordinator node 302, the second virtual-experience server sends (at 315b) other first state information associated with the first frame of the second region to the coordinator node 302, and the third virtual-experience server 304c sends (at 315c) another first state information associated with the first frame of the third zone to the coordinator node 302.

Referring to FIG. 3B, the coordinator node 302 may store (at 317) the state information associated with the checkpoint interval for each of the regions.

At a time that corresponds to a second frame of the simulated virtual world, the first virtual-experience server 304a may simulate (at 319a) a second frame of the first region, the third virtual-experience server 304c may simulate (at 319c) a second frame of the third region, and the client device 306 may simulate (at 319d) a second frame of the second region.

Prior to the simulation of the second frame of the second region, the second virtual-experience server 304b may experience a failure (at 319b). The failure may occur for various reasons such as, e.g., a power outage at the second virtual-experience server 304b, a reduction in network bandwidth at the second virtual-experience server 304b, a workload-capacity threshold being reached, etc. When a failure occurs and communication with the coordinator node 302 is maintained, the second virtual-experience server 304b may send (at 321) an indication of the performance failure to the coordinator node 302. Otherwise, if communication with the coordinator node 302 fails, the coordinator node 302 may determine the performance failure when signaling from the second virtual-experience server 304b is not received for a threshold duration.

In the non-limiting example depicted in FIG. 3B, a script managed by the third virtual-experience server 304c may generate an inter-region message associated with the second frame of second region. For instance, if another user’s avatar located in the third region interacts with an object during the second frame that causes an effect in the second region, the third virtual-experience server 304c may send (at 323) a corresponding inter-region message, which is stored (at 325) by the coordinator node 302.

To enable vault-streaming recovery for the second region, the coordinator node 302 may determine (at 327) the available workload capacity of the first virtual-experience server 304a and the third virtual-experience server 304c (e.g., the functional servers). If the available workload capacity of the first virtual-experience server 304a can support the simulation of the second region, the coordinator node 302 may request (at 329) the first virtual-experience server 304a perform recovery simulation of the second frame of the second region. In some implementations, the request may indicate the workload capacity for simulating the second region. The first virtual-experience server 304a may send (at 331) an indication that it will manage the simulation for the second region.

Referring to FIG. 3C, the coordinator node 302 may send (at 333) the other first state information associated with the first frame of the second region and inter-region message associated with the second frame of the second region to the first virtual-experience server 304a. The coordinator node 302 may determine which virtual-experience servers store replicated state information for the second region. In the non-limiting example depicted in FIG. 3C, the third virtual-experience server 304c stores replicated state information for the second region. Thus, the coordinator node 302 may send (at 335) an indication that the third virtual-experience server 304c stores replicated state information for the second region to the first virtual-experience server 304a.

Moreover, the coordinator node 302 may send (at 337) an indication that the simulation of the second region is reassigned to the first virtual-experience server 304a to the client device 306. In some implementations, the client device 306 may request reassignment information from the coordinator node 302 when the second virtual-experience server 304b stops communication with the client device 306. In either case, once notified, the client device 306 may establish (at 339) communication with first virtual-experience server 304a. In some implementations, the client device 306 may send (at 341) definitive state information associated with the last simulated frame to the first virtual-experience server.

The first virtual-experience server 304a may perform (at 343) a recovery simulation of the second frame of the second region. The first virtual-experience server 304a may reconstruct the second region as of the second frame using 1) the other first state information of the first frame (e.g., the last checkpoint of that same region) and 2) all the inter-region messages have been received (at 333) from the coordinator node 302.

Once recovery simulation of second frame of the second region is complete, the first virtual-experience server 304a may send (at 345) replicated state information associated with the second frame of the second region to the third virtual-experience server 304c. Although not shown, if the second frame is associated with another checkpoint interval, the state information of the second frame of each region will also be sent to the coordinator node 302.

Still referring to FIG. 3C, in some cases, the first virtual-experience server 304a may determine (at 347) a reduction in its workload capacity. A reduction in workload capacity may occur for various reasons, e.g., such as when the network throughput reaches a threshold level, the latency of over-the-air communications reaches a threshold level, when the internal temperature of the first virtual-experience server 304a reaches a threshold level, when the computational workload of simulating the first and/or region(s) increases to a threshold level, etc. When a reduction in workload capacity occurs, the first virtual-experience server 304a may send (at 349) an indication that its workload capacity is reduced to the coordinator node 302.

Based on the reduction in workload capacity, the coordinator node 302 may reassign the second region to another virtual-experience server. To that end, the coordinator node 302 may determine (at 351) whether the available workload capacity of the third virtual-experience server 304c can support the recovery simulation of the second region. If its workload capacity can support recovery simulation of the second region, the coordinator node 302 may send (at 353) a reassignment indication for the second region to the third virtual-experience server 304c.

Referring to FIG. 3D, the third virtual-experience server 304c may perform (at 355) recovery simulation of the second region. Here, if the reduction in workload capacity of the first virtual-experience server 304a occurs after the simulation of the second frame and before the simulation of the third frame, the third virtual-experience server 304c may perform (at 355) the simulation recovery of the second region starting with the third frame. Although not shown, to facilitate the recovery simulation of the second region by the third virtual-experience server 304c, the coordinator node 302, the third virtual-experience server 304c, and the client device 306 may perform the same or similar operations as those described above with reference to operations 331-341.

In some implementations, the second virtual-experience server 304b may determine (at 357) that its performance recovers and is once again able to manage the simulation of the second region. This may occur when the second virtual-experience server 304b regains power or when the network conditions become more favorable, for example. When performance recovery occurs, the second virtual-experience server 304b may send (at 359) an indication that its performance is recovered and can once again manage the simulation of the second region to the coordinator node 302.

As such, the coordinator node 302 sends (at 361) a message indicating to the third virtual-experience server 304c that the second region is reassigned to the second virtual-experience server 304b. In response to the indication, the third virtual-experience server 304c may send (at 363) the current state information for the second region to the coordinator node 302. Additionally and/or alternatively, the third virtual-experience server 304c may send the current state information for the second region to the second virtual-experience server 304b.

The coordinator node 302 may send (at 365) a message instructing the second virtual-experience server 304b to manage the simulation of the second region. The second virtual-experience server 304b may send (at 367) an acceptance message, indicating it will manage the simulation for the second region. In response to the acceptance indication, the coordinator node 302 may send (at 369) an indication that the second region to the client device 306. The client device 306 may establish (at 371) communication with the second virtual-experience server 304b and send (at 373) definitive state information as of the previous frame to the second virtual-experience server 304b and/or the coordinator node 302. In some implementations, the third virtual-experience server 304c may send (at 375) current state information for the second region as of the previous frame to the coordinator node 302. Additionally and/or alternatively, the third virtual-experience server 304c may send the current state information directly to the second virtual-experience server 304b.

Referring to FIG. 3E, the coordinator node 302 may send (at 377) the current state information and any inter-region messages received since the last checkpoint interval to the second virtual-experience server 304b. In implementations in which the client device 306 sends the definitive state information to the second virtual-experience server 304b, the coordinator node may only send (at 377) the inter-region messages. The second virtual-experience server 304b may simulate (at 379) the next frame of the second region by running the physics and scripts based on, e.g., one or more of the current state information, the definitive state information, and the inter-region messages.

While the above-described vault-streaming recovery technique provides various advantages over existing techniques, it may suffer from some shortcomings.

For instance, vault-streaming recovery involves storing inter-region messages from every region in the virtual experience by the coordinator node 302. This includes inter-region messages that would be internal to a virtual-experience server during normal operation. Suppose the second virtual-experience server 304b maintains the primary copies of state information for two adjacent regions A and B, and neither region has a replica on another server. If an object migrates from region A to region B, this normally does not require an inter-region message to be sent over the network, since the simulation of both the source region and the destination region are managed by the same virtual-experience server. However, if the second virtual-experience server 304b fails and regions A and B are respectively assigned to the first virtual-experience server 304a and the third virtual-experience server 304c for simulation recovery, the third virtual-experience server 304c will need the migration inter-region message to reconstruct the state of region B.

Moreover, if regions are assigned randomly to new servers for simulation recovery, additional boundaries are created for which replicas need to be communicated and stored. This is because when the first virtual-experience server 304a manages region A, which is adjacent to another region B managed by the second virtual-experience server 304b, the first virtual-experience server 304a must have a replica of region B for the physics simulation to work properly. Additional signaling overhead is created because replicas require communication to remain synchronized with their primary copies. Thus, if region A but not region B is reassigned to the third virtual-experience server 304c, an additional boundary is created, thereby increasing the amount of signaling overhead.

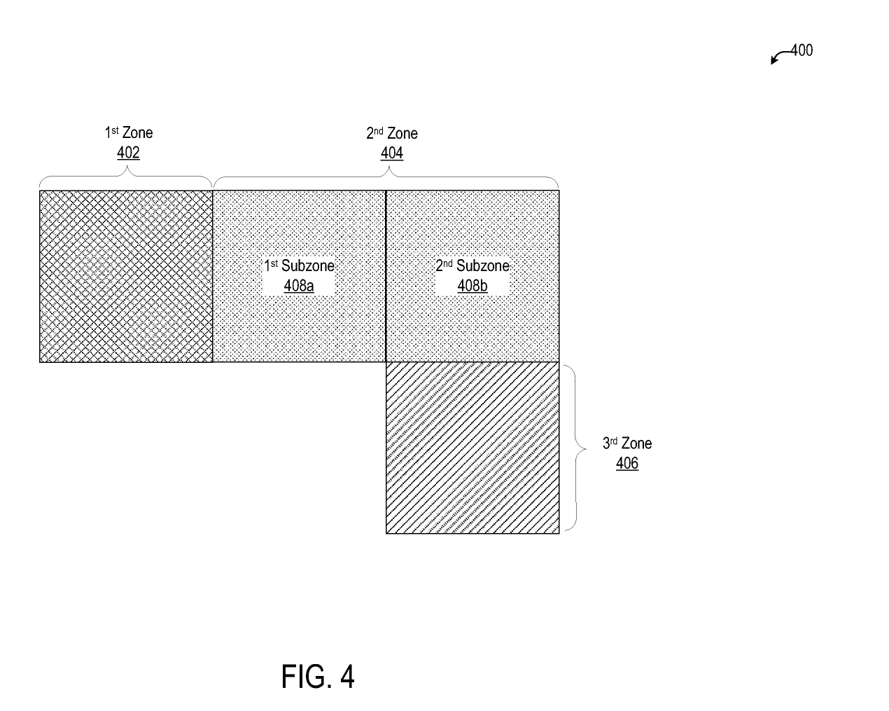

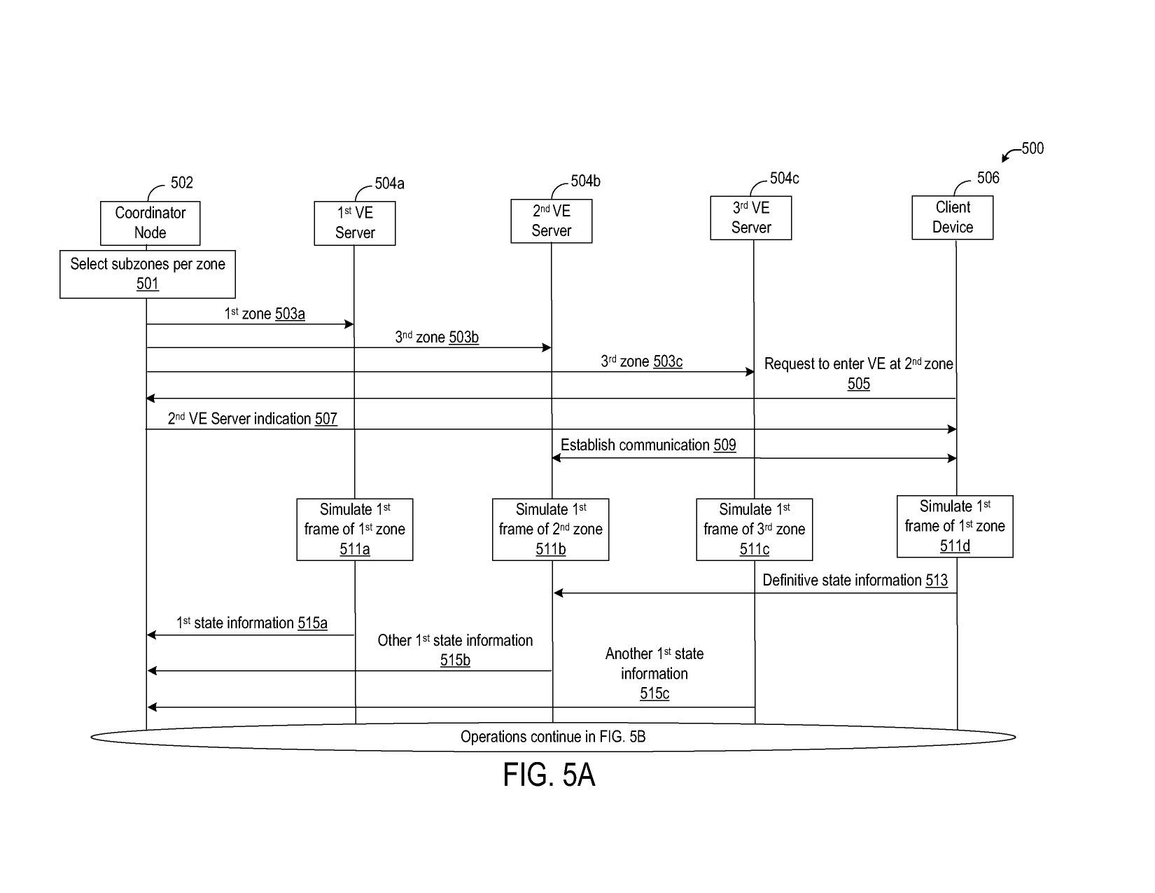

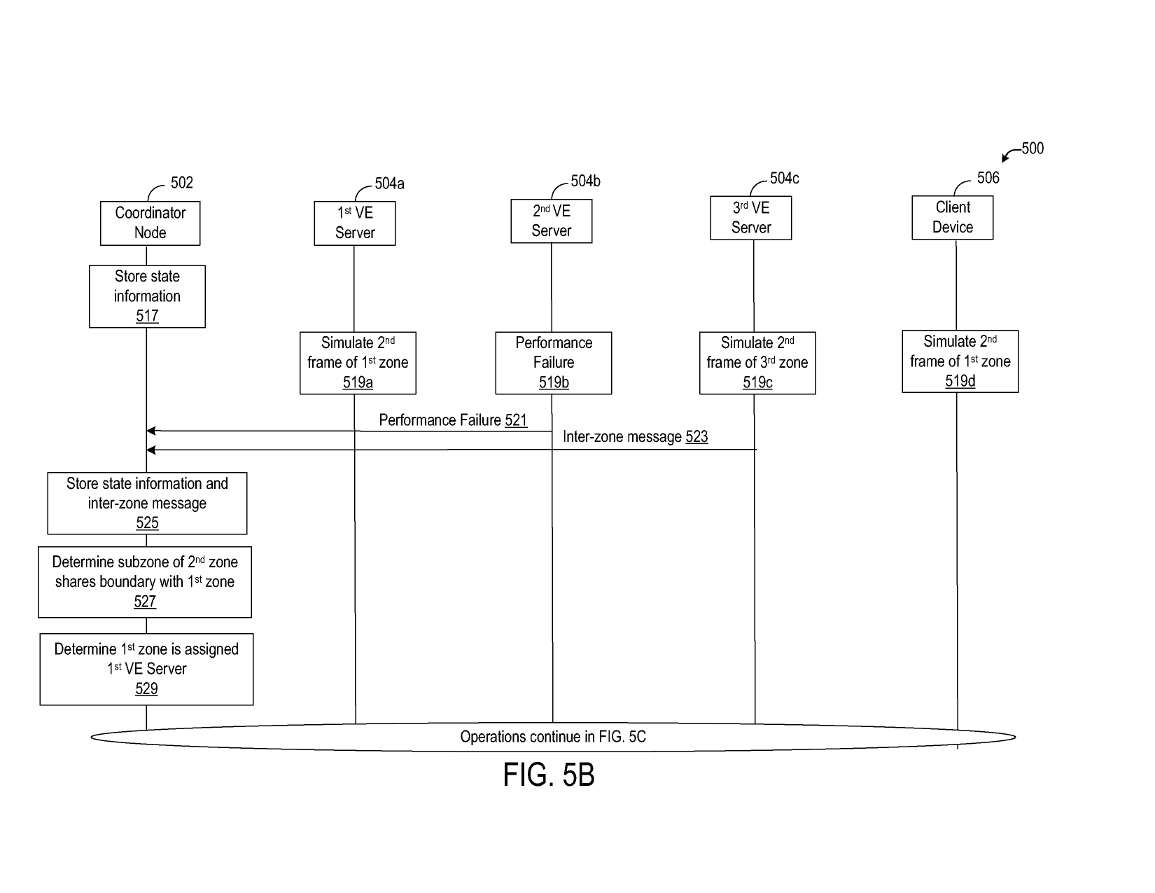

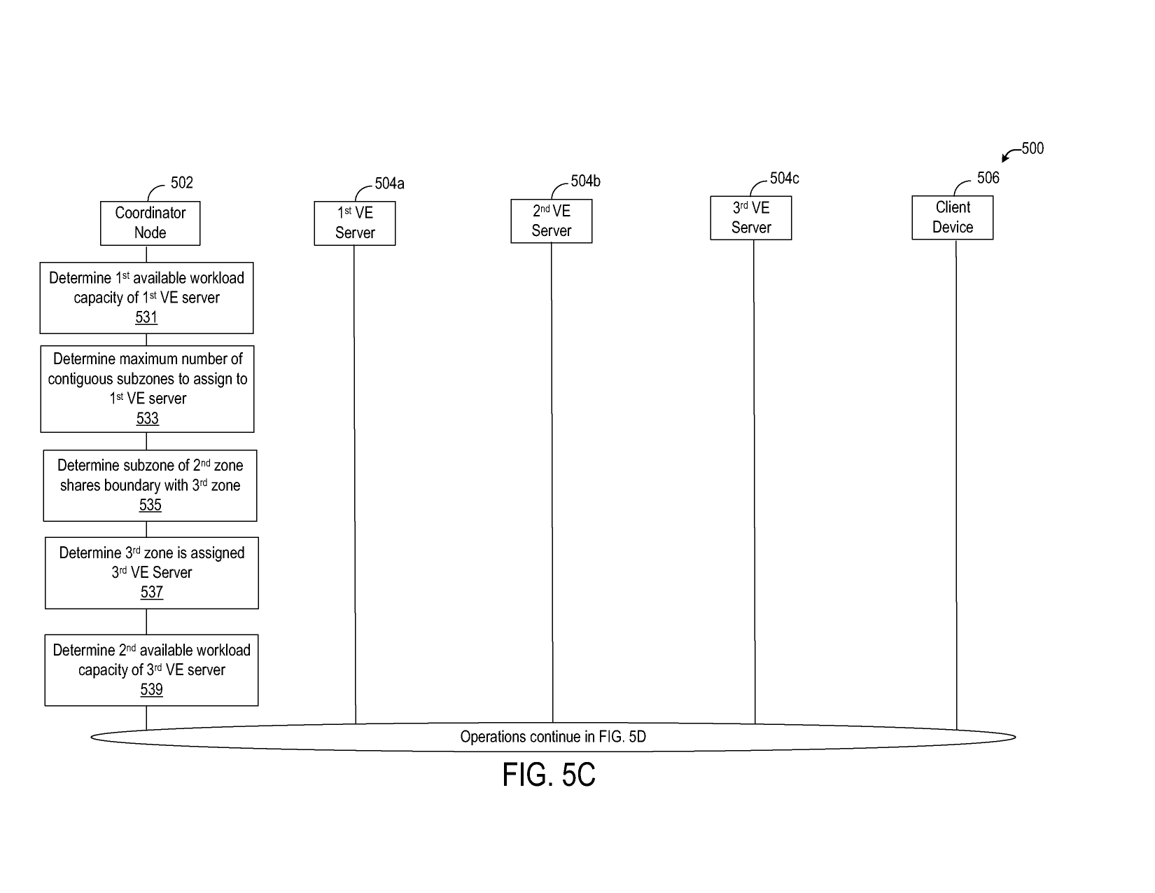

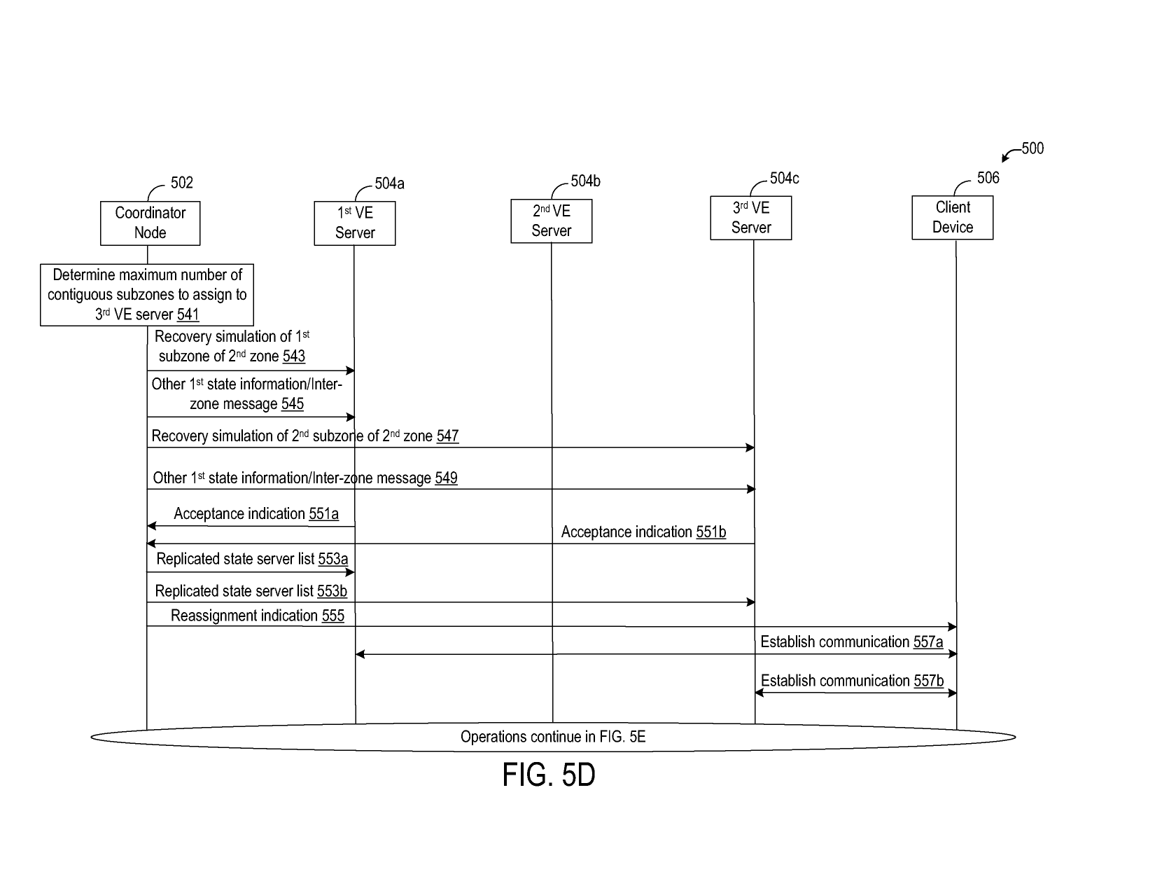

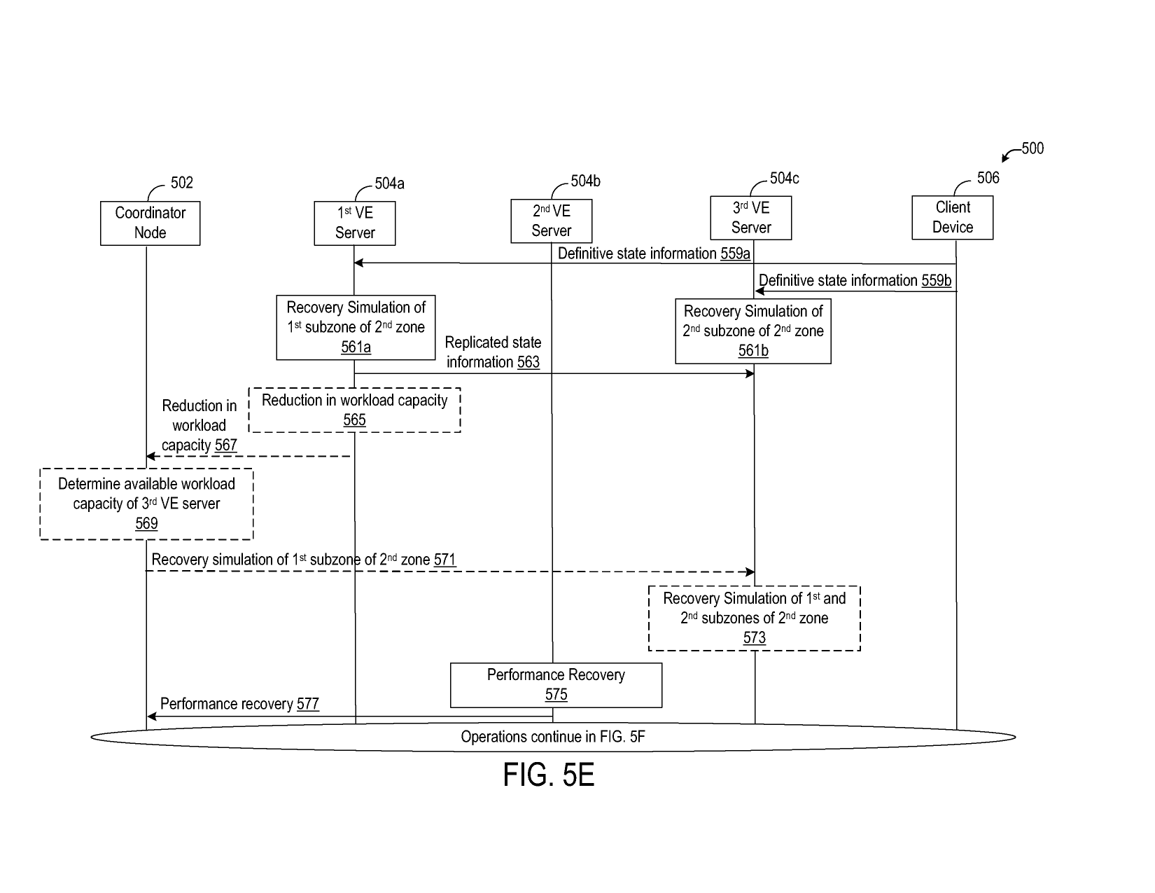

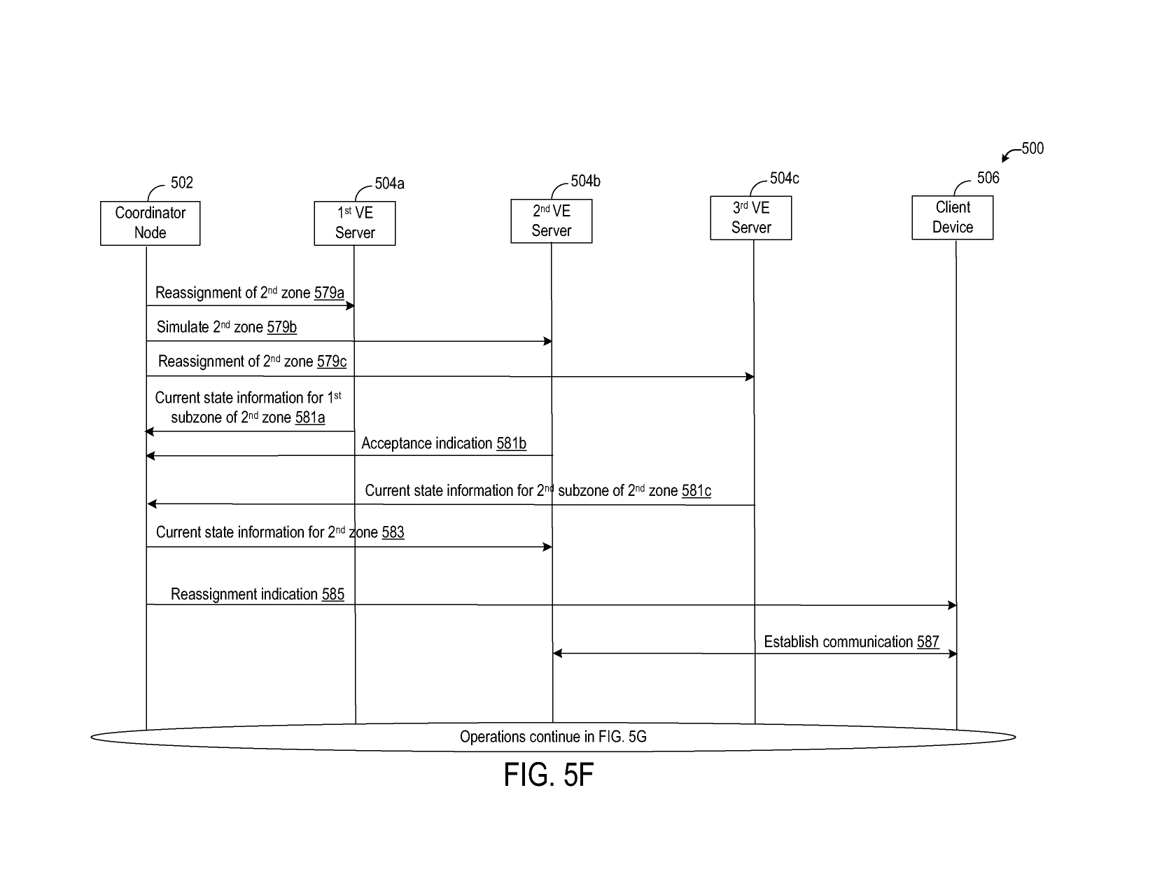

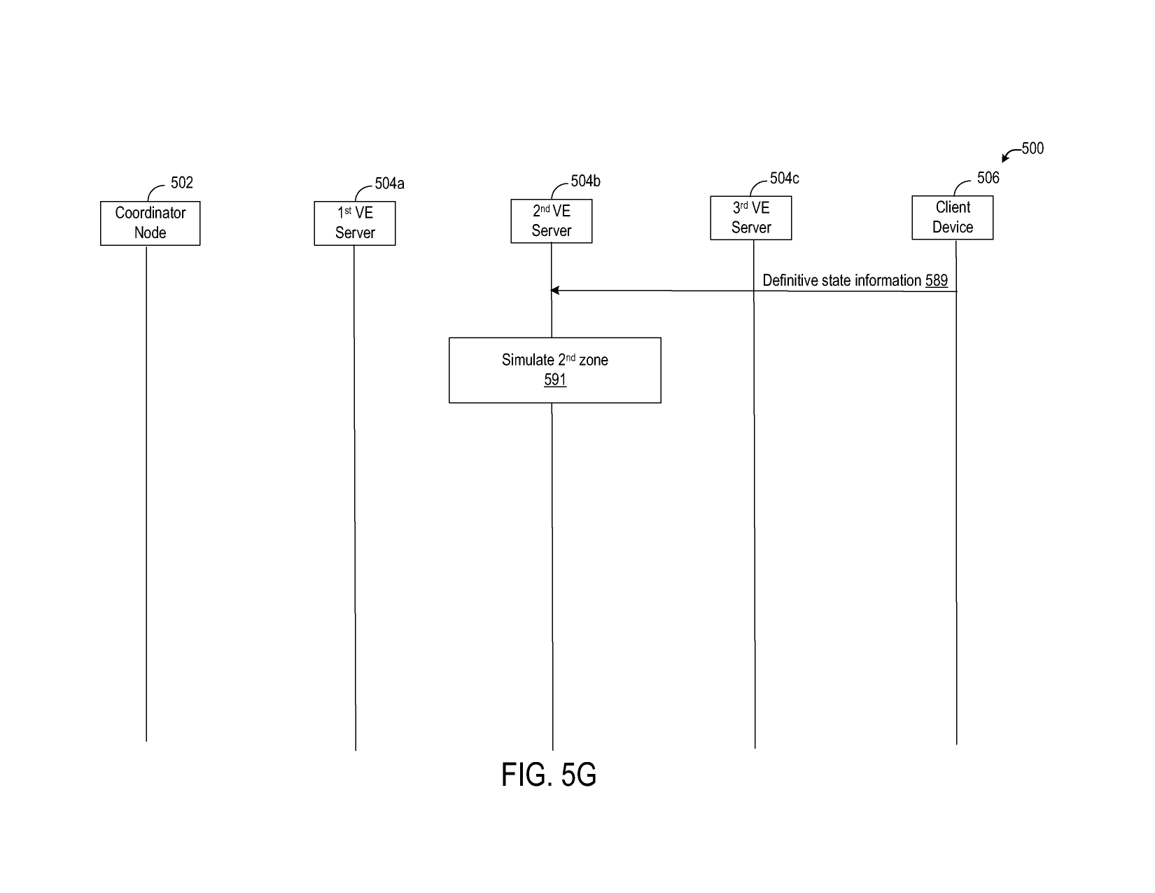

The topology-aware recovery technique described below with reference to FIGS. 4 and 5A-5G does not suffer from these shortcomings, however.

### FIG. 4: Example Zones of a Virtual Experience

FIG. 4 is a diagram illustrating example zones and sub-zones of a virtual space 400, in accordance with some implementations.

To avoid the above-mentioned shortcomings of vault-streaming recovery, the topology-aware recovery technique groups regions of the virtual space into zones. A zone is simply a contiguous group of regions, which is ideally convex to minimize its perimeter. By assigning the regions in a zone to the same virtual-experience server for simulation, the amount of overhead signaling is limited, since inter-region messages for the same zone will not need to be sent over the network and replicas are created only for regions at zone boundaries (and only if the other zone is managed by a different virtual-experience server). Additionally, if an entire zone is assigned to the same virtual-experience server for simulation recovery, vault streaming for any intra-zone messages is avoided, since they will not be needed during recovery.

To that end, each zone may be divided into multiple subzones. A subzone is a contiguous and convex part of a zone. This enables the reassignment of a zone’s subzones to different virtual-experience servers during recovery. To further reduce signaling overhead once recovery is complete, subzones may be assigned to virtual-experience servers that already simulate zones with which one of the reassigned subzones shares a boundary.

In the non-limiting example shown in FIG. 4, the virtual space 400 is divided into a first zone 402, a second zone 404, and a third zone 406. Each of these zones may include a grouping of one or more regions of the virtual space 400. Moreover, each of these zones may be subdivided into subzones. For instance, the second zone 404 is divided into a first subzone 408a and a second subzone 408b. The first subzone 408a shares a boundary with the first zone 402, while the second subzone 408b shares a boundary with third zone 406. Although not shown, the first zone 402 and the third zone 406 may also be subdivided into respective subzones.

By way of example and not limitation, assume the first zone 402 is assigned to virtual-experience server X, the second zone 404 is assigned to virtual-experience server Y, and the third zone 406 is assigned to virtual-experience server Z. If virtual-experience server Y fails, the first subzone 408a is reassigned to virtual-experience server X rather than virtual-experience server Z, and the second subzone 408b is reassigned to virtual-experience server Z rather than virtual-experience server X. This is because after simulation recovery, the boundary between the first zone 402 and the first subzone 408a will be internal to virtual-experience server X, and the boundary between the third zone 406 and the second subzone 408b will be internal to virtual-experience server Z. Consequently, inter-zone messages are not required between the first zone 402 and the first subzone 408a nor the third zone 406 and the second subzone 408b, thereby limiting the amount of overhead signaling.

It is understood that the virtual space 400 may include more or fewer than three zones, and each zone may be subdivided into two or more subzones. Moreover, the size and shape of each zone may be equal or different, and the size and shape of each subzone may be the same or different.

Additional details of topology-aware recovery are provided below with reference to FIGS. 5A-5G.

### FIGS. 5A-5G: Example Call Flow Diagram for Topology-Aware Recovery

FIGS. 5A-5G are a call flow diagram illustrating second example operations 500 for simulation recovery, in accordance with some implementations. As shown in FIGS. 5A-5G, the example operations may be performed by, e.g., a coordinator node 502, a first virtual-experience server 504a, a second virtual-experience server 504b, a third virtual-experience server 504c, and a client device 506. The coordinator node 502 may be configured as one or more servers and/or a central set of machines in a data center. It is understood that more or fewer virtual-experience servers and client devices may be associated with the virtual experience than those depicted in FIGS. 5A-5G. Optional operations may be indicated with dashed lines in FIGS. 5A-5G.

Referring to FIG. 5A, the coordinator node 502 selects (at 501) a number of regions, zones, and subzones per zone. For example, coordinator node 502 may divide the virtual world into a plurality of contiguous spatial regions, each containing spatially located objects. Each region is determined so that each physics island is either contained entirely within the region or spans only regions that are adjacent. Each physics island is formed by one or more connected objects and at least one corresponding virtual-experience script associated with the one or more connected objects. In other words, coordinator node 502 may divide the virtual space into regions so that the computational workload associated with simulating the one or more connected objects is associated with spatial locality.

Moreover, coordinator node 502 may group the regions into zones. A zone is simply a contiguous group of regions, which is ideally convex to minimize its perimeter. Still further, the coordinator node 502 may divide the zones into a number of subzones. The number of subzones per zone may be selected based on one or more of a target speed of simulation recovery or a number of frames associated with each checkpoint interval, for example.

In the non-limiting example of FIG. 5A, the coordinator node 502 may determine three zones of the virtual world and two subzones per zone. The coordinator node 502 may assign each of the three zones to a respective virtual-experience server. For example, the coordinator node 502 may assign (at 503a) the first zone to the first virtual-experience server 504a, assign (at 503b) the second zone to the second virtual-experience server 504b, and assign (at 503c) the third zone to the third virtual-experience server 504c.

The coordinator node 502 may maintain a registry that maps corresponding zones and objects to their respective virtual-experience servers. As mentioned above, the state of the registry may be derived from the state information stored at the virtual-experience servers and can be rebuilt by having each virtual-experience server report which zones and objects it contains.

The client device 506 may request (at 505) to enter the virtual experience in the second zone, for example. Upon receipt of the request, the coordinator node 502 may access the registry and determine the second zone is currently managed by the second virtual-experience server 504b. The coordinator node 502 may send (at 507) a message to indicate to the client device 506 that the second virtual-experience server 504b manages the second zone. The client device 506 may establish (at 509) communication with the second virtual-experience server 504b, which enables the user to interact with the virtual experience.

At a time period corresponding to a first frame of the simulated virtual experience, the first virtual-experience server 504a may simulate (at 511a) a first frame of the first zone, the second virtual-experience server 504b may simulate (at 511b) a first frame of the second zone, the third virtual-experience server 504c may simulate (at 511c) a first frame of the third zone, and the client device 506 may simulate (at 511d) a first frame of the second zone.

Each virtual-experience server simulates the frame i+1 of its corresponding region according to the following. For instance, the second virtual-experience server 504b may apply the inputs received from the client device 506 (e.g., key presses) that would affect the velocity or orientation of a user’s avatar. The physics simulation is completed for objects in the second zone for which the second virtual-experience server 504b maintains the primary copy.

Still using the second zone as an example, the second virtual-experience server 504b may further simulate the first frame by executing scripts for the second zone. A script may be executed by receiving any incoming inter-zone messages associated with the previous frame, and executing each script based on the state information of the previous frame and the inter-zone messages. If the scripts have inter-zone messages to send, the second virtual-experience server 504b may use the registry to identify the corresponding server(s) that maintain copies (primary or replica) of the destination objects and transmit the messages to these servers. An inter-zone message may be generated when an avatar in one zone performs an action that affects an object in another zone that is not managed by the same server. In some implementations, the second virtual-experience server 504b may maintain a copy of the registry, which it access directly. In some other implementations, the second virtual-experience server 504b may access the registry via the coordinator node 502.

Still referring to FIG. 5A, the client device 506 may send (at 513) definitive state information associated with its avatar’s actions in the second zone to the second virtual-experience server 504b and/or the coordinator node 502. The second virtual-experience server 504b may update the state information it maintains for the second zone based on the definitive state information.

In response to the first frame being associated with a first checkpoint interval, the first virtual-experience server may send (at 515a) first state information associated with the first frame of the first zone to the coordinator node 502, the second virtual-experience server may send (at 515b) other first state information associated with the first frame of the second zone to the coordinator node 502, and the third virtual-experience server 504c may send (at 515c) another first state information associated with the first frame of the third zone to the coordinator node 502.

Referring to FIG. 5B, the coordinator node 502 may store (at 517) the state information associated with the check point interval for each of the zones.

At a time period that corresponds to a second frame of the simulated virtual world, the first virtual-experience server 504a may simulate (at 519a) a second frame of the first zone, the third virtual-experience server 504c may simulate (at 519c) a second frame of the third zone, and the client device 506 may simulate (at 519d) a second frame of the second zone.

Prior to the simulation of the second frame of the second zone, the second virtual-experience server 504b may experience a failure (at 519b). The failure may occur for various reasons, e.g., such as a power outage at the second virtual-experience server 504b, a reduction in network bandwidth at the second virtual-experience server 504b, a workload-capacity threshold being reached, etc. When a failure occurs, the second virtual-experience server 504b may send (at 521) an indication of the performance failure to the coordinator node 502. Otherwise, signaling from the second virtual-experience server 504b is not received within a predetermined duration, the coordinator node 502 may determine the performance failure without receiving a message.

In the non-limiting example depicted in FIG. 5B, a script managed by the third virtual-experience server 504c may generate an inter-zone message associated with the second frame of second zone. For instance, if another user’s avatar located in the third zone performs an action that has an effect in the second zone, the third virtual-experience server 504c may send (at 523) a corresponding inter-zone message, which is stored (at 525) by the coordinator node 502.

Still referring to FIG. 5B, in response to the performance failure of the second virtual-experience server 504b, the coordinator node 502 may determine (at 527) the first subzone of the second zone shares a boundary with the first zone. Using the registry, the coordinator node 502 may determine (at 529) the first zone is managed by the first virtual-experience server 504a.

Referring to FIG. 5C, the coordinator node 502 may determine (at 531) the available workload capacity of the first virtual-experience server 504a. Then, the coordinator node 502 may determine (at 533) the maximum number of contiguous subzones of the second zone to reassign to the first virtual-experience server 504a based on its available workload capacity.

Assuming the available workload capacity of the first virtual-experience server 504a cannot also support reassignment of the second subzone of the second zone, the coordinator node 502 may determine which zone shares a boundary with the second subzone of the second zone. In the non-limiting example shown in FIG. 5C, the coordinator node 502 may determine (at 535) the second subzone of the second zone shares a boundary with the third zone. Using the registry, the coordinator node 502 may determine (at 537) the third zone is managed by the third virtual-experience server 504c. Then, the coordinator node 502 may determine (at 539) the available workload capacity of the third virtual-experience server 504c.

Referring to FIG. 5D, the coordinator node 502 may determine (at 541) a maximum number of contiguous subzones of the second zone to reassign to the third virtual-experience server 504c. In the present non-limiting example, there is only one remaining subzone (e.g., the second subzone) that needs reassignment. Once the reassignment of the second zone’s subzones is determined, the coordinator node 502 may send (at 543) a message reassigning the first subzone of the second zone to the first virtual-experience server 504a. The coordinator node 502 may also send (at 545) the other first state information and any inter-zone messages for the script(s) of the first subzone of the second zone to the first virtual-experience server 504a.

For reassignment of the second subzone of the second zone, the coordinator node 502 may send (at 547) an indication to the third virtual-experience server 504c. Moreover, the coordinator node 502 may send (at 549) the other first state information and any inter-zone messages for the script(s) of the second subzone of the second zone to the third virtual-experience server 504c.

In some implementations, the respective reassignment messages may indicate the workload capacity for simulating the first subzone and the second subzone. The first virtual-experience server 504a may send (at 551a) an indication that it accepts the reassignment of first subzone of the second zone, and the third virtual-experience server 504c may send (at 551b) an indication that it accepts the reassignment of the second subzone of the second zone.

Once the acceptance indications are received, the coordinator node 502 may send (at 553a) a replicated state server list for the second zone or the first subzone of the second zone to the first virtual-experience server 504a. Similarly, the coordinator node 502 may send (at 553b) a replicated server list for the second zone or the second subzone of the second zone to the third virtual-experience server 504c.

Still referring to FIG. 5D, the coordinator node 502 may send (at 555) a reassignment indication of the first and second subzones of the second zone to the client device 506. The client device 506 may establish (at 557a) communication with the first virtual-experience server 504a and establish (at 557b) communication with the third virtual-experience server 504c.

Referring to FIG. 5E, the client device 506 may send (at 559a) definitive state information as of the last frame to the first virtual-experience server 504a. The client device 506 may also send (at 559b) the definitive state information to the third virtual-experience server 504c. Using one or more of the other first state information, the definitive state information, and/or inter-zone messages that affect their respective subzones, the first virtual-experience server 504a may perform (at 561a) recovery simulation for the first subzone of the second zone, and the third virtual-experience server 504c may perform (at 561b) recovery simulation for the second subzone of the second zone.

Each of the first virtual-experience server 504a and the third virtual-experience server 504c may send corresponding replicated state information to the virtual-experience servers indicated in the list received from the coordinator node 502. In the example depicted in FIG. 5E, the third virtual-experience server 504c maintains the replicated state information for the first subzone of the second zone. Thus, the first virtual-experience server 504a sends (at 563) replicated state information associated with the second frame simulated for the first subzone of the second zone to the third virtual-experience server 504c.

In some instances, the first virtual-experience server 504a may determine (at 565) a reduction in its workload capacity. A reduction in workload capacity may occur for various reasons, e.g., such as when the network throughput reaches a threshold level, the latency of over-the-air communications reaches a threshold level, when the internal temperature of the first virtual-experience server 504a reaches a threshold level, when the computational workload of simulating the first and/or region(s) increases to a threshold level, etc. When a reduction in workload capacity occurs, the first virtual-experience server 504a may send (at 567) an indication that its workload capacity can no longer support the management of the first subzone of the second zone or the first zone to the coordinator node 502.

Based on the reduction in workload capacity, the coordinator node 502 may reassign the first subzone of the second zone (or the first zone) to another virtual-experience server. To that end, the coordinator node 502 may determine (at 569) whether the available workload capacity of the third virtual-experience server 504c can support the recovery simulation of the first subzone of the second zone. If its available workload capacity can support this additional subzone, the coordinator node 502 may send (at 571) a reassignment indication to the third virtual-experience server 504c.

The third virtual-experience server 504c may perform (at 573) recovery simulation of the first subzone of the second zone. Here, if the reduction in workload capacity of the first virtual-experience server 504a occurs after it simulated the second frame and before the simulation of the third frame, the third virtual-experience server 504c may perform (at 573) the simulation recovery of the first subzone of the second zone starting with the third frame. Although not shown, to facilitate the recovery simulation of the first subzone of the second zone by the third virtual-experience server 504c, the coordinator node 502, the third virtual-experience server 504c, and the client device 506 may perform the same or similar operations as those described above with reference to operations 545-553b.

In some implementations, the second virtual-experience server 504b may determine (at 575) that its performance recovers and is once again able to manage the simulation of the second zone. This may occur when the second virtual-experience server 504b regains power or when the network conditions become more favorable, for example. When performance recovery occurs, the second virtual-experience server 504b may send (at 577) an indication that its performance is recovered and can once again manage the simulation of the second zone to the coordinator node 502.

Referring to FIG. 5F, the following description of operations to reassign the second zone to the second virtual-experience server 504b is provided with the assumption the first virtual-experience server 504a did not experience a reduction in workload capacity, and hence, still manages the simulation of the first subzone of the second zone when the performance of the second virtual-experience server 504b recovers.

As such, the coordinator node 502 may send (at 579a) a message indicating to the first virtual-experience server 504a that the first subzone of the second zone is reassigned to the second virtual-experience server 504b. The coordinator node 502 may send (at 579b) a reassignment message associated with the second zone to the second virtual-experience server 504b. The coordinator node 502 may send (at 579c) a message indicating to the third virtual-experience server 504c that the second subzone of the second zone is reassigned to the second virtual-experience server 504b.

In response to the reassignment indication, the first virtual-experience server 504a may send (at 581a) the current state information for the first subzone of the second zone to the coordinator node 502, the second virtual-experience server 504b may send (at 581b) an indication of acceptance for the reassignment of the second zone to the coordinator node 502, and the third virtual-experience server 504c may send (at 581c) the current state information for the second subzone of the second zone to the coordinator node 502.

The coordinator node 502 may send (at 583) the current state information for the first and second subzones of the second zone to the second virtual-experience server 504b. Additionally and/or alternatively, the first virtual-experience server 504a and/or the third virtual-experience server 504c may send the current state information for their respective subzones of the second zone to the second virtual-experience server 504b.

In response to the acceptance indication from the second virtual-experience server 504b, the coordinator node 502 may send (at 585) an indication of reassignment to the client device 506. The client device 506 may establish (at 587) communication with the second virtual-experience server 504b.

Referring to FIG. 5G, the client device may send (at 589) definitive state information as of the previous frame to the second virtual-experience server 504b and/or the coordinator node 502. Using one or more of the current state information, the definitive state information, and/or inter-zone messages, the second virtual-experience server 504b may simulate (at 591) the second zone.

In this way, topology-aware recovery technique is achieved with a limited number of virtual-experience servers and a limited amount of network overhead.

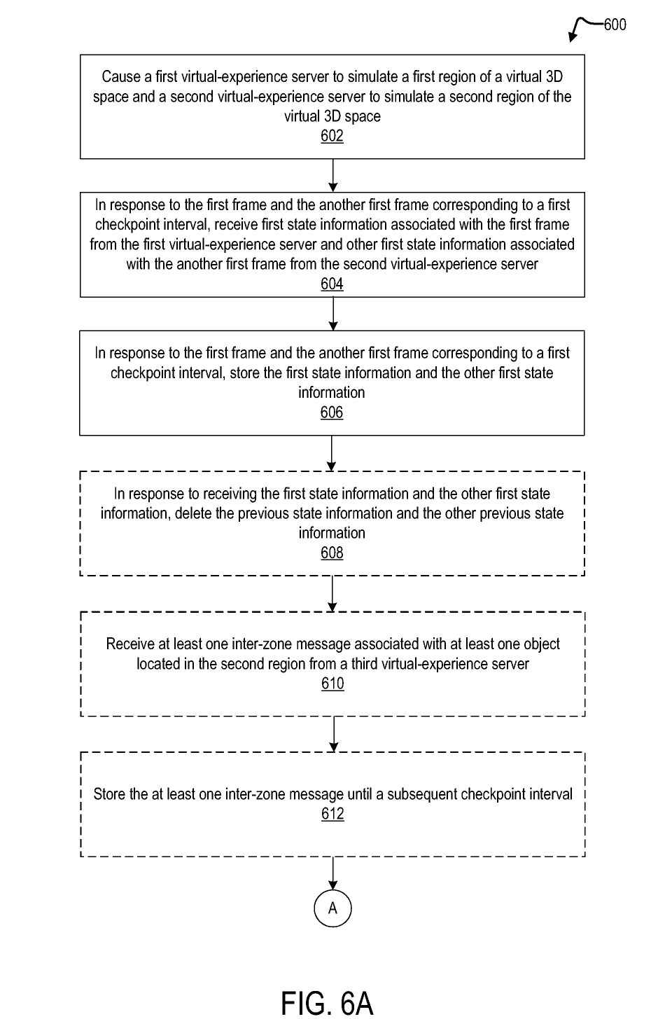

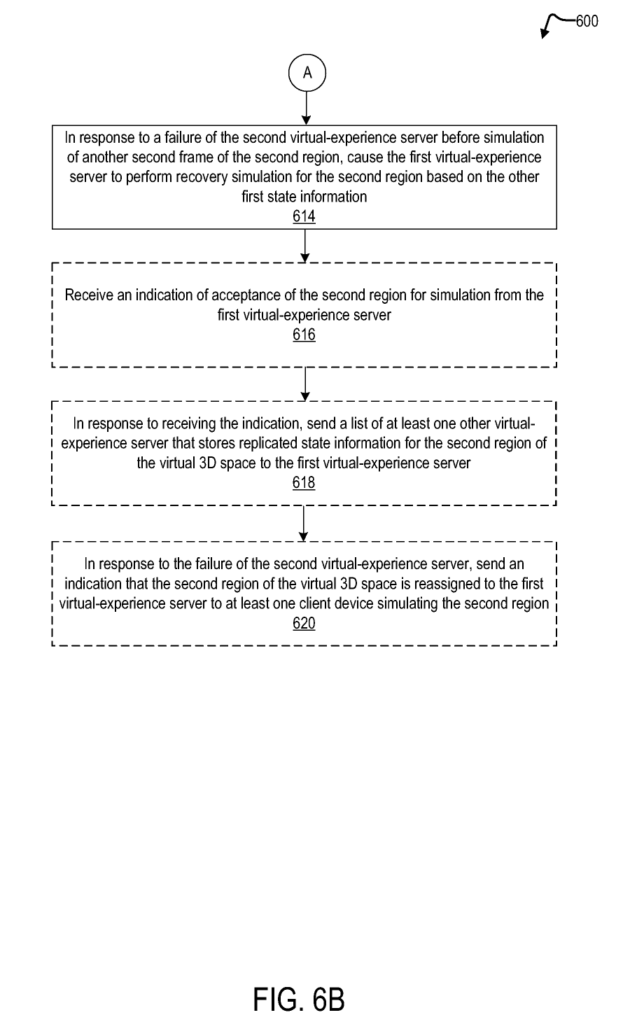

### FIGS. 6A and 6B: First Example Method of Simulation Recovery by a Coordinator Node

FIGS. 6A and 6B are a flowchart of a first example method 600 to perform simulation recovery by a coordinator node, in accordance with some implementations. In FIGS. 6A and 6B, optional operations are indicated with dashed lines.

In some implementations, method 600 can be implemented, for example, on an online virtual experience server 102 described with reference to FIG. 1. In some implementations, some or all of the method 600 can be implemented on one or more client devices 110 as shown in FIG. 1, on one or more developer devices (not illustrated), or on one or more server device(s), and/or on a combination of developer device(s), server device(s) and client device(s). In described examples, the implementing system includes one or more digital processors or processing circuitry (“processors”), and one or more storage devices (e.g., a data store 108 or other storage). In some implementations, different components of one or more servers and/or clients can perform different blocks or other parts of the method 600. In some examples, a coordinator node is described as performing blocks of method 600. Some implementations can have one or more blocks of method 600 performed by one or more other devices (e.g., other client devices or server devices) that can send results or data to the first device.

In some implementations, method 600, or portions of the method(s) described herein, can be initiated automatically by a system. In some implementations, the implementing system is a device. For example, the method (or portions thereof) can be periodically performed, or performed based on one or more particular events or conditions, e.g., the failure of a virtual-experience server, check point intervals, and/or one or more other conditions occurring which can be specified in settings read by the methods.

Referring to FIG. 6A, method 600 may begin at block 602. At block 602, a first virtual-experience server is caused to simulate a first region of a virtual 3D space and a second virtual-experience server to simulate a second region of the virtual 3D space.

In some implementations, the first virtual-experience server simulates a first frame of the first region by running at least one first virtual-experience model using previous state information associated with a previous frame of the first region. In some implementations, the second virtual-experience server simulates another first frame of the second region by running at least one second virtual-experience model using other previous state information associated with another previous frame of the second region.

Block 602 may be followed by block 604. At block 604, in response to the first frame and the another first frame corresponding to a first checkpoint interval, first state information associated with the first frame is received from the first virtual-experience server and other first state information associated with the another first frame is received from the second virtual-experience server.

Block 604 may be followed by block 606. At block 606, in response to the first frame and the another first frame corresponding to a first checkpoint interval, the first state information and the other first state information are stored.

Block 606 may be followed by block 608. At block 608, in response to receiving the first state information and the other first state information, the previous state information and the other previous state information are deleted.

Block 608 may be followed by block 610. At block 610, at least one inter-region message associated with at least one object located in the second region is received from a third virtual-experience server.

Block 610 may be followed by block 612. At block 612, the at least one inter-zone message is stored until a subsequent checkpoint interval.

Referring to FIG. 6B, block 612 may be followed by block 614. At block 614, in response to a failure of the second virtual-experience server before simulation of another second frame of the second region, the first virtual-experience server is caused to perform recovery simulation for the second region based on the other first state information.

In some implementations, the first virtual-experience server performs the recovery simulation by running the at least one second virtual-experience model using the other first state information.

In some implementations, causing the first virtual-experience server to perform the recovery simulation for the second region may include sending the other first state information and the at least one inter-zone message to first virtual-experience server. In some implementations, causing the first virtual-experience server to perform the recovery simulation for the second region may include causing the first virtual-experience server to perform recovery simulation for the second region based on the other first state information and the at least one inter-zone message. In some implementations, the first virtual-experience server performs the recovery simulation by running the at least one second virtual-experience model using the other first state information and the at least one inter-zone message.

Block 614 may be followed by block 616. At block 616, an indication of acceptance of the second region for simulation is received from the first virtual-experience server.

Block 616 may be followed by block 618. At block 618, in response to receiving the indication, a list of at least one other virtual-experience server that stores replicated state information for the second region of the virtual 3D space is sent to the first virtual-experience server.

Block 618 may be followed by block 620. At block 620, in response to the failure of the second virtual-experience server, an indication that the second region of the virtual 3D space is reassigned to the first virtual-experience server is sent to at least one client device simulating the second region.

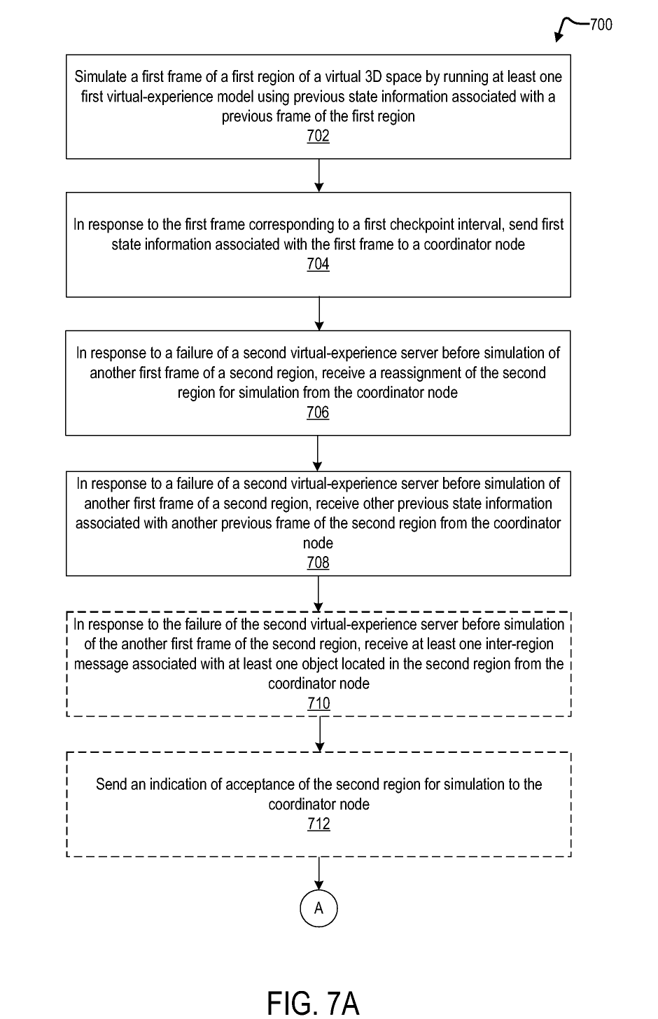

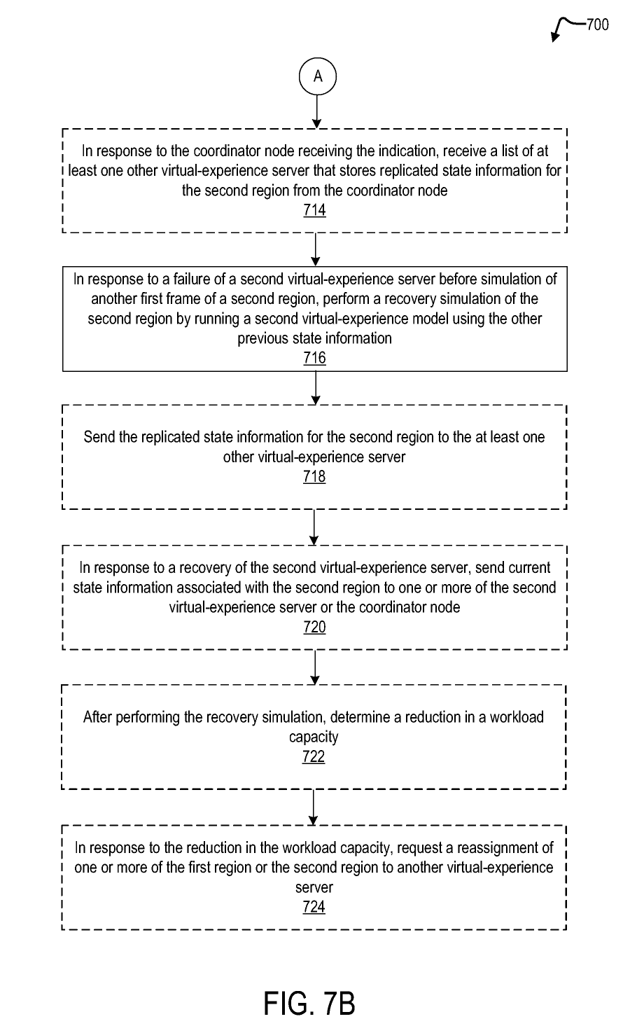

### FIGS. 7A and 7B: First Example Method of Simulation Recovery by a Virtual-Experience Server

FIGS. 7A and 7B are a flowchart of a first example method 700 to perform simulation recovery by a virtual-experience server, in accordance with some implementations. In FIGS. 7A and 7B, optional operations are indicated with dashed lines.

In some implementations, method 700 can be implemented, for example, on an online virtual experience server 102 described with reference to FIG. 1. In some implementations, some or all of the method 700 can be implemented on one or more client devices 110 as shown in FIG. 1, on one or more developer devices (not illustrated), or on one or more server device(s), and/or on a combination of developer device(s), server device(s) and client device(s). In described examples, the implementing system includes one or more digital processors or processing circuitry (“processors”), and one or more storage devices (e.g., a data store 108 or other storage). In some implementations, different components of one or more servers and/or clients can perform different blocks or other parts of the method 700. In some examples, a coordinator node is described as performing blocks of method 700. Some implementations can have one or more blocks of method 700 performed by one or more other devices (e.g., other client devices or server devices) that can send results or data to the first device.

In some implementations, method 700, or portions of the method(s) described herein, can be initiated automatically by a system. In some implementations, the implementing system is a device. For example, the method (or portions thereof) can be periodically performed, or performed based on one or more particular events or conditions, e.g., the failure of a virtual-experience server, check point intervals, and/or one or more other conditions occurring which can be specified in settings read by the methods.

Referring to FIG. 7A, method 700 may begin at block 702. At block 702, a first frame of a first region of a virtual 3D space is simulated by running at least one first virtual-experience model using previous state information associated with a previous frame of the first region.

Block 702 may be followed by block 704. At block 704, in response to the first frame corresponding to a first checkpoint interval, first state information associated with the first frame is sent to a coordinator node.

Block 704 may be followed by block 706. At block 706, in response to a failure of a second virtual-experience server before simulation of another first frame of a second region, a reassignment of the second region for simulation is received from the coordinator node.

Block 706 may be followed by block 708. At block 708, in response to a failure of a second virtual-experience server before simulation of another first frame of a second region, other previous state information associated with another previous frame of the second region is received from the coordinator node.

Block 708 may be followed by block 710. At block 710, in response to the failure of the second virtual-experience server before simulation of the another first frame of the second region, at least one inter-region message associated with at least one object located in the second region is received from the coordinator node.

Block 710 may be followed by block 712. At block 712, an indication of acceptance of the second region for simulation is sent to the coordinator node.

Referring to FIG. 7B, block 712 may be followed by block 714. At block 714, in response to the coordinator node receiving the indication, a list of at least one other virtual-experience server that stores replicated state information for the second region is received from the coordinator node.

Block 714 may be followed by block 716. At block 716, in response to a failure of a second virtual-experience server before simulation of another first frame of a second region, a recovery simulation of the second region is performed by running a second virtual-experience model using the other previous state information.

In some implementations, performing the recovery simulation of the second region by running the second virtual-experience model using the other previous state information and the at least one inter-region message.

Block 716 may be followed by block 718. At block 718, the replicated state information for the second region is sent to the at least one other virtual-experience server.

Block 718 may be followed by block 720. At block 720, in response to a recovery of the second virtual-experience server, current state information associated with the second region is sent to one or more of the second virtual-experience server or the coordinator node.

Block 720 may be followed by block 722. At block 722, after performing the recovery simulation, a reduction in a workload capacity is determined.

Block 722 may be followed by block 724. At block 724, in response to the reduction in the workload capacity, a reassignment of one or more of the first region or the second region to another virtual-experience server is requested.

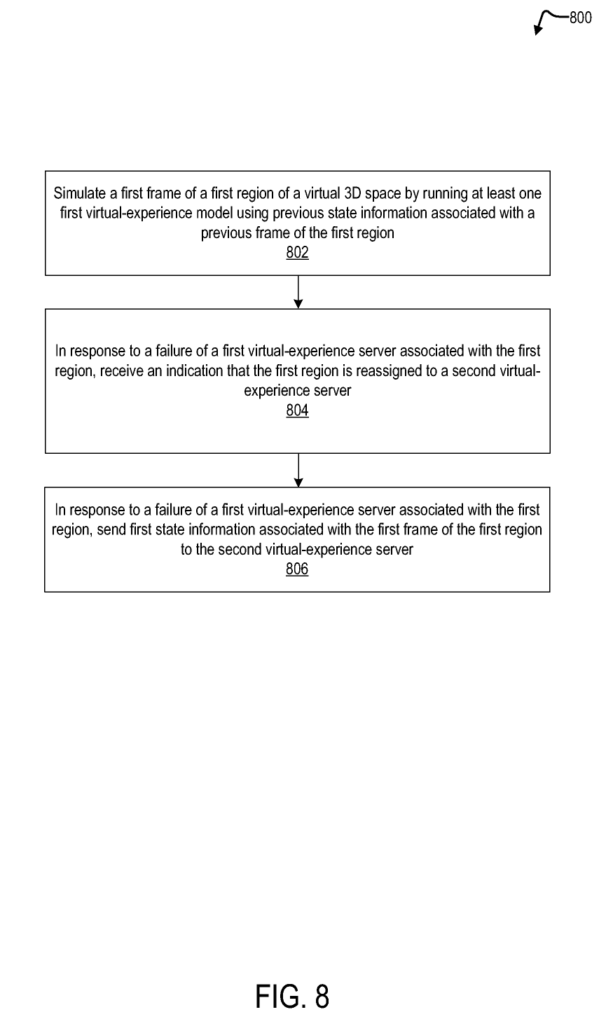

### FIG. 8: First Example Method of Simulation Recovery by a Client Device

FIG. 8 is a flowchart of a first example method 800 to perform simulation recovery by a client device, in accordance with some implementations.

In some implementations, some or all of the method 800 can be implemented on one or more client devices 110 as shown in FIG. 1, on one or more developer devices (not illustrated), or on one or more server device(s), and/or on a combination of developer device(s), server device(s) and client device(s). In described examples, the implementing system includes one or more digital processors or processing circuitry (“processors”), and one or more storage devices (e.g., a data store 108 or other storage). In some implementations, different components of one or more servers and/or clients can perform different blocks or other parts of the method 800. In some examples, a coordinator node is described as performing blocks of method 800. Some implementations can have one or more blocks of method 800 performed by one or more other devices (e.g., other client devices or server devices) that can send results or data to the first device.

In some implementations, method 800, or portions of the method(s) described herein, can be initiated automatically by a system. In some implementations, the implementing system is a device. For example, the method (or portions thereof) can be periodically performed, or performed based on one or more particular events or conditions, e.g., the failure of a virtual-experience server, check point intervals, and/or one or more other conditions occurring which can be specified in settings read by the methods.

Referring to FIG. 8, the method 800 may begin at block 802. At block 802, a first frame of a first region of a virtual 3D space is simulated by running at least one first virtual-experience model using previous state information associated with a previous frame of the first region.

In some implementations, each region is associated with at least one corresponding physics island. In some implementations, each physics island is formed by one or more connected objects and at least one corresponding virtual-experience script associated with the one or more connected objects. In some implementations, a computational workload associated with simulating the one or more connected objects is associated with spatial locality.

Block 802 may be followed by block 804. At block 804, in response to a failure of a first virtual-experience server associated with the first region, an indication that the first region is reassigned to a second virtual-experience server is received.

Block 804 may be followed by block 806. At block 806, in response to a failure of a first virtual-experience server associated with the first region, first state information associated with the first frame of the first region is sent to the second virtual-experience server.

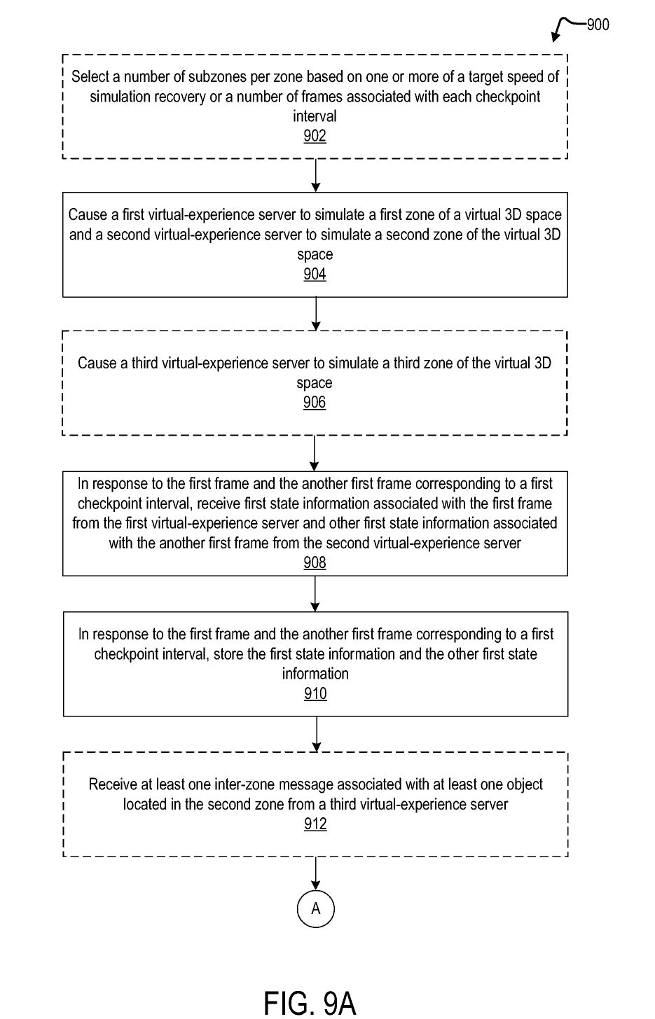

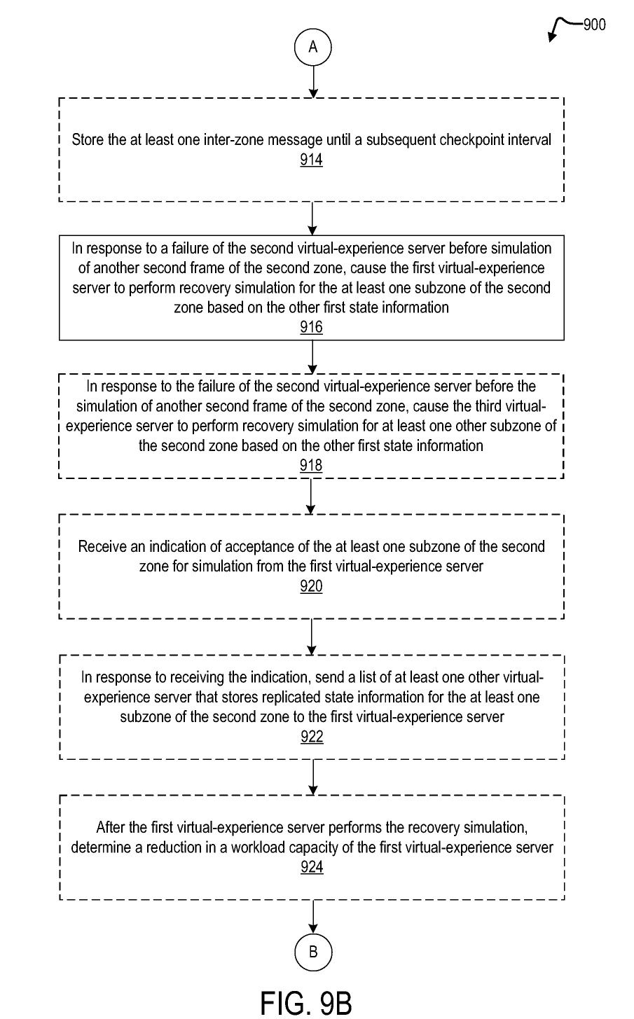

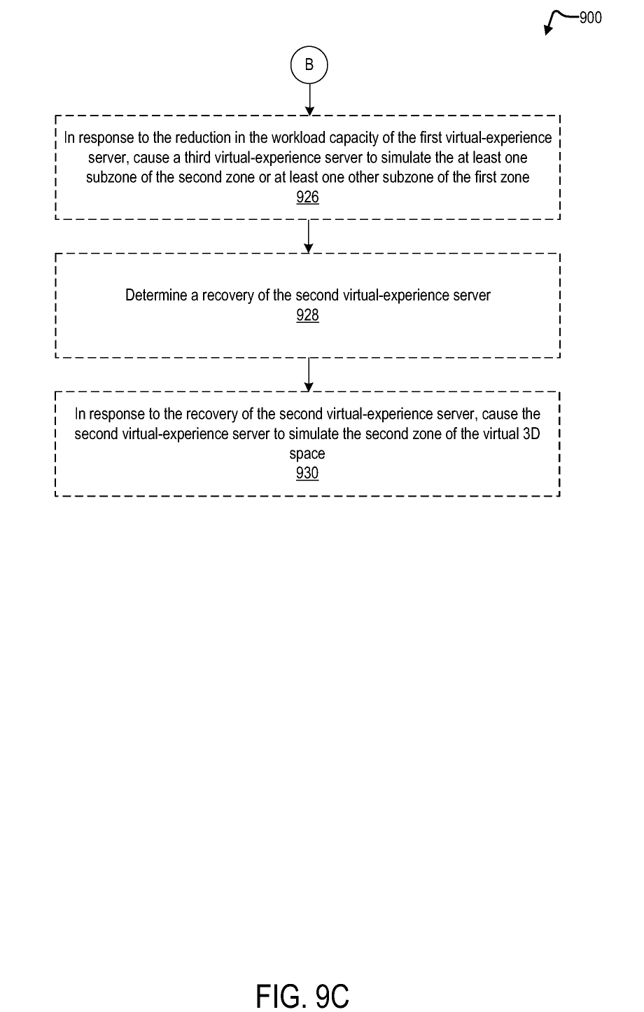

### FIGS. 9A-9C: Second Example Method of Simulation Recovery by a Coordinator Node

FIGS. 9A-9C are a flowchart of a second example method 900 to perform simulation recovery by a coordinator node, in accordance with some implementations. In FIGS. 9A-9C, optional operations are indicated with dashed lines.

In some implementations, method 900 can be implemented, for example, on an online virtual experience server 102 described with reference to FIG. 1. In some implementations, some or all of the method 900 can be implemented on one or more client devices 110 as shown in FIG. 1, on one or more developer devices (not illustrated), or on one or more server device(s), and/or on a combination of developer device(s), server device(s) and client device(s). In described examples, the implementing system includes one or more digital processors or processing circuitry (“processors”), and one or more storage devices (e.g., a data store 108 or other storage). In some implementations, different components of one or more servers and/or clients can perform different blocks or other parts of the method 900. In some examples, a coordinator node is described as performing blocks of method 900. Some implementations can have one or more blocks of method 900 performed by one or more other devices (e.g., other client devices or server devices) that can send results or data to the first device.

In some implementations, method 900, or portions of the method(s) described herein, can be initiated automatically by a system. In some implementations, the implementing system is a device. For example, the method (or portions thereof) can be periodically performed, or performed based on one or more particular events or conditions, e.g., the failure of a virtual-experience server, check point intervals, and/or one or more other conditions occurring which can be specified in settings read by the methods.

Referring to FIG. 9A, method 900 may begin at block 902. At 902, a number of subzones per zone is selected based on one or more of a target speed of simulation recovery or a number of frames associated with each checkpoint interval.

In some implementations, at least one subzone of the second zone shares a boundary in the virtual 3D space with the first zone. In some implementations, the first virtual-experience server simulates a first frame of the first zone by running at least one first virtual-experience model using previous state information associated with a previous frame of the first zone, the second virtual-experience server simulates another first frame of the second zone by running at least one second virtual-experience model using other previous state information associated with another previous frame of the second zone.

In some implementations, each zone of the virtual 3D space may include a respective plurality of subzones, each subzone may include at least one region associated with at least one corresponding physics island, each physics island may be formed by one or more connected objects and at least one corresponding virtual-experience script associated with the one or more connected objects, and a computational workload associated with simulating the one or more connected objects may be associated with spatial locality.

In some implementations, the first virtual-experience server simulates a first frame of the first region by running at least one first virtual-experience model using previous state information associated with a previous frame of the first region, and the second virtual-experience server simulates another first frame of the second region by running at least one second virtual-experience model using other previous state information associated with another previous frame of the second region.

Block 902 may be followed by block 904. At block 904, a first virtual-experience server is caused to simulate a first zone of a virtual 3D space and a second virtual-experience server to simulate a second zone of the virtual 3D space.

In some implementations, at least one subzone of the second zone shares a boundary in the virtual 3D space with the first zone. In some implementations, the first virtual-experience server simulates a first frame of the first zone by running at least one first virtual-experience model using previous state information associated with a previous frame of the first zone, the second virtual-experience server simulates another first frame of the second zone by running at least one second virtual-experience model using other previous state information associated with another previous frame of the second zone.

Block 904 may be followed by block 906. At block 906, a third virtual-experience server is caused to simulate a third zone of the virtual 3D space.

Block 906 may be followed by block 908. At block 908, in response to the first frame and the another first frame corresponding to a first checkpoint interval, first state information associated with the first frame is received from the first virtual-experience server and other first state information associated with the another first frame is received from the second virtual-experience server.

Block 908 may be followed by block 910. At block 910, in response to the first frame and the another first frame corresponding to a first checkpoint interval, the first state information and the other first state information are stored.

Block 910 may be followed by block 912. At block 912, at least one inter-zone message associated with at least one object located in the second zone is received from a third virtual-experience server.

Referring to FIG. 9B, block 912 may be followed by block 914. At block 914, the at least one inter-zone message is stored until a subsequent checkpoint interval.

Block 914 may be followed by block 916. At block 916, in response to a failure of the second virtual-experience server before simulation of another second frame of the second zone, the first virtual-experience server is caused to perform recovery simulation for the at least one subzone of the second zone based on the other first state information.

In some implementations, the first virtual-experience server performs the recovery simulation by running the at least one second virtual-experience model using a portion of the other first state information corresponding to the at least one subzone.

In some implementations, causing the first virtual-experience server to perform the recovery simulation for the at least one subzone of the second zone may include sending the other first state information and the at least one inter-zone message to first virtual-experience server. In some implementations, the first virtual-experience server performs the recovery simulation of the another second frame of the second zone by running the at least one second virtual-experience model using the portion of the other first state information and the at least one inter-zone message.

In some implementations, by causing the first virtual-experience server to perform the recovery simulation for the at least one subzone of the second zone that shares the boundary with the first zone, no inter-zone messages associated with objects in the first zone and the at least one subzone of the second zone and used for simulation are sent over a network during simulation of the first zone and the at least one subzone after the recovery simulation.

In some implementations, causing the first virtual-experience server to perform the recovery simulation for the at least one subzone of the second zone may include determining the at least one subzone of the second zone shares the boundary with the first zone in the virtual 3D space. In some implementations, causing the first virtual-experience server to perform the recovery simulation for the at least one subzone of the second zone may include determining the first zone is assigned to the first virtual-experience server based on a registry that indicates assignments of virtual-experience servers to zones of the virtual 3D space. In some implementations, causing the first virtual-experience server to perform the recovery simulation for the at least one subzone of the second zone may include determining a first available workload capacity of the first virtual-experience server based on its simulation of the first zone. In some implementations, causing the first virtual-experience server to perform the recovery simulation for the at least one subzone of the second zone may include a maximum number of first contiguous subzones of the second zone that includes the at least one subzone. In some implementations, a first collective workload of the first contiguous subzones may not exceed the first available workload capacity of the first virtual-experience server. In some implementations, causing the first virtual-experience server to perform the recovery simulation for the at least one subzone of the second zone may include causing the first virtual-experience server to perform the recovery simulation for the maximum number of first contiguous subzones of the second zone.

Block 916 may be followed by block 918. At block 918, in response to the failure of the second virtual-experience server before the simulation of another second frame of the second zone, the third virtual-experience server is caused to perform recovery simulation for at least one other subzone of the second zone based on the other first state information.

In some implementations, the third virtual-experience server performs the recovery simulation of the another second frame of the second zone by running the at least one second virtual-experience model using another portion of the other first state information corresponding to the at least one other subzone, and the at least one other subzone of the second zone shares a boundary with the third zone in the virtual 3D space.

In some implementations, causing the third virtual-experience server to simulate the third zone of the virtual 3D space may include determining the at least one other subzone of the second zone shares the boundary with the third zone. In some implementations, the at least one other subzone may be excluded from the maximum number of first contiguous subzones. In some implementations, causing the third virtual-experience server to simulate the third zone of the virtual 3D space may include determining the third zone is assigned to the third virtual-experience server based on the registry that indicates assignments of virtual-experience servers to zones of the virtual 3D space. In some implementations, causing the third virtual-experience server to simulate the third zone of the virtual 3D space may include determining a second available workload capacity of the third virtual-experience server. In some implementations, causing the third virtual-experience server to simulate the third zone of the virtual 3D space may include a maximum number of second contiguous subzones of the second zone that includes the at least one other subzone. In some implementations, a second collective workload of the second contiguous subzones may not exceed the second available workload capacity of the third virtual-experience server. In some implementations, causing the third virtual-experience server to simulate the third zone of the virtual 3D space may include causing the third virtual-experience server to perform the recovery simulation for the maximum number of second contiguous subzones of the second zone.

Block 918 may be followed by block 920. At block 920, an indication of acceptance of the at least one subzone of the second zone for simulation is received from the first virtual-experience server.

Block 920 may be followed by block 922. At block 922, in response to receiving the indication, a list of at least one other virtual-experience server that stores replicated state information for the at least one subzone of the second zone is sent to the first virtual-experience server.

Block 922 may be followed by block 924. At block 924, after the first virtual-experience server performs the recovery simulation, a reduction in a workload capacity of the first virtual-experience server is determined.

Referring to FIG. 9C, block 924 may be followed by block 926. At block 926, in response to the reduction in the workload capacity of the first virtual-experience server, a third virtual-experience server is caused to simulate the at least one subzone of the second zone or at least one other subzone of the first zone.

Block 926 may be followed by block 928. At block 928, a recovery of the second virtual-experience server is determined.

Block 928 may be followed by block 930. At block 930, in response to the recovery of the second virtual-experience server, the second virtual-experience server is caused to simulate the second zone of the virtual 3D space.

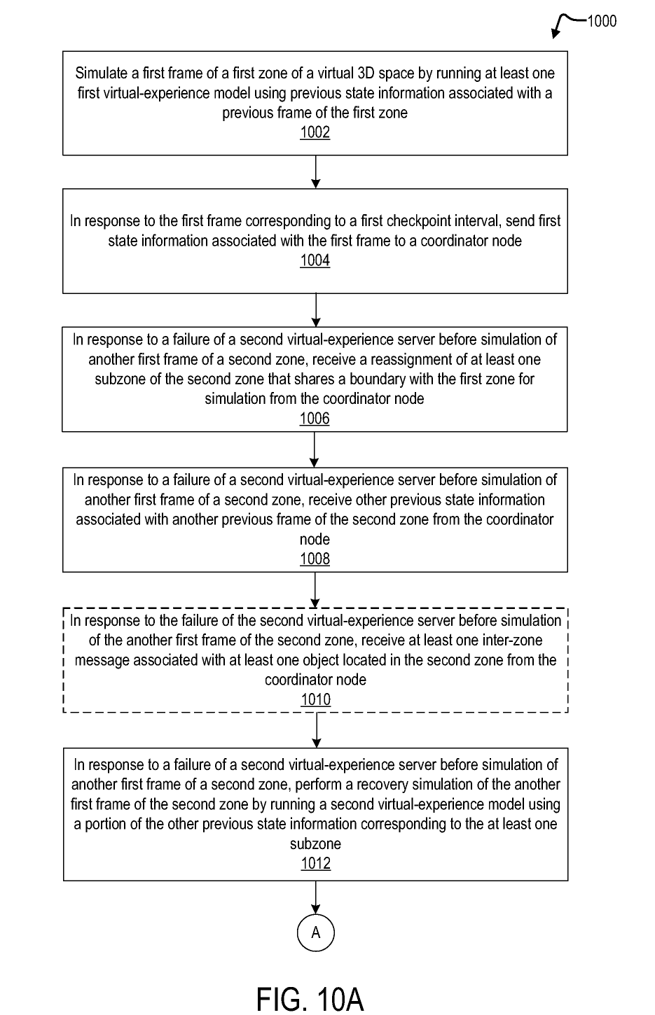

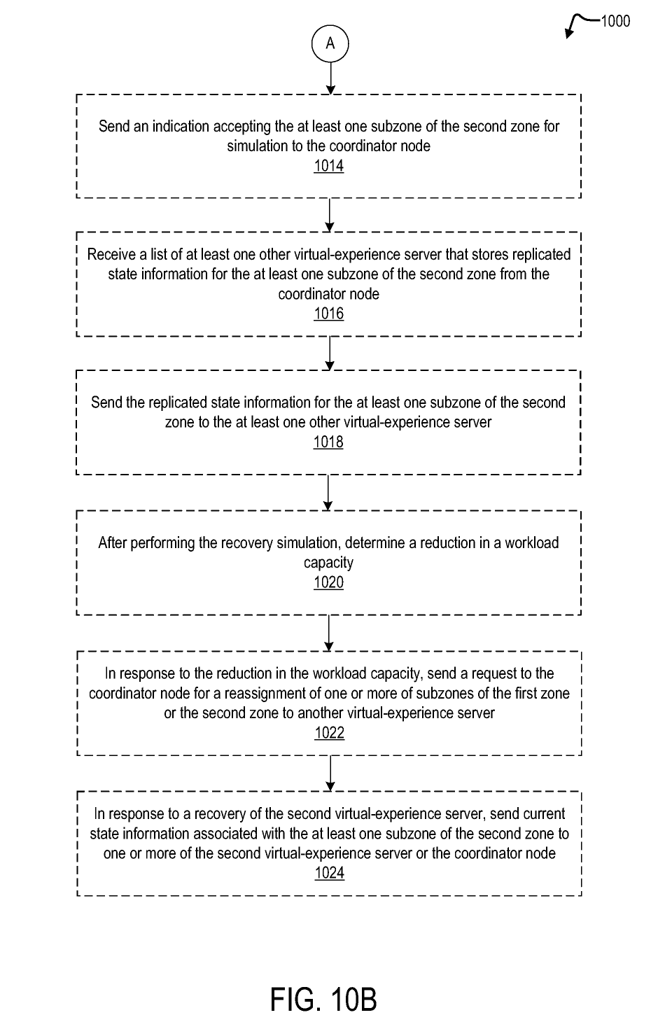

### FIGS. 10A and 10B: Second Example Method of Simulation Recovery by a Virtual-Experience Server

FIGS. 10A and 10B are a flowchart of a second example method 1000 to perform simulation recovery by a virtual-experience server, in accordance with some implementations. In FIGS. 10A and 10B, optional operations are indicated with dashed lines.

In some implementations, method 1000 can be implemented, for example, on an online virtual experience server 102 described with reference to FIG. 1. In some implementations, some or all of the method 1000 can be implemented on one or more client devices 110 as shown in FIG. 1, on one or more developer devices (not illustrated), or on one or more server device(s), and/or on a combination of developer device(s), server device(s) and client device(s). In described examples, the implementing system includes one or more digital processors or processing circuitry (“processors”), and one or more storage devices (e.g., a data store 108 or other storage). In some implementations, different components of one or more servers and/or clients can perform different blocks or other parts of the method 1000. In some examples, a coordinator node is described as performing blocks of method 1000. Some implementations can have one or more blocks of method 1000 performed by one or more other devices (e.g., other client devices or server devices) that can send results or data to the first device.

In some implementations, method 1000, or portions of the method(s) described herein, can be initiated automatically by a system. In some implementations, the implementing system is a device. For example, the method (or portions thereof) can be periodically performed, or performed based on one or more particular events or conditions, e.g., the failure of a virtual-experience server, check point intervals, and/or one or more other conditions occurring which can be specified in settings read by the methods.

Referring to FIG. 10A, method 1000 may begin at block 1002. At block 1002, a first frame of a first zone of a virtual 3D space is simulated by running at least one first virtual-experience model using previous state information associated with a previous frame of the first zone.

Block 1002 may be followed by block 1004. At block 1004, in response to the first frame corresponding to a first checkpoint interval, first state information associated with the first frame is sent to a coordinator node.

Block 1004 may be followed by block 1006. At block 1006, in response to a failure of a second virtual-experience server before simulation of another first frame of a second zone, a reassignment of at least one subzone of the second zone that shares a boundary with the first zone for simulation is received from the coordinator node.

Block 1006 may be followed by block 1008. At block 1008, in response to a failure of a second virtual-experience server before simulation of another first frame of a second zone, other previous state information associated with another previous frame of the second zone is received from the coordinator node.

Block 1008 may be followed by block 1010. At block 1010, in response to the failure of the second virtual-experience server before simulation of the another first frame of the second zone, at least one inter-zone message associated with at least one object located in the second zone is received from the coordinator node.

Block 1010 may be followed by block 1012. At block 1012, in response to a failure of a second virtual-experience server before simulation of another first frame of a second zone, a recovery simulation of the another first frame of the second zone is performed by running a second virtual-experience model using a portion of the other previous state information corresponding to the at least one subzone.

In some implementations, performing the recovery simulation of the another first frame of the at least one subzone of the second zone may include simulating the another first frame of the at least one subzone of the second zone by running the second virtual-experience model using the portion of the other previous state information and the at least one inter-zone message.

Referring to FIG. 10B, block 1012 may be followed by block 1014. At block 1014, an indication accepting the at least one subzone of the second zone for simulation is sent to the coordinator node.

Block 1014 may be followed by block 1016. At block 1016, a list of at least one other virtual-experience server that stores replicated state information for the at least one subzone of the second zone is received from the coordinator node.

Block 1016 may be followed by block 1018. At block 1018, the replicated state information for the at least one subzone of the second zone is sent to the at least one other virtual-experience server.

Block 1018 may be followed by block 1020. At block 1020, after performing the recovery simulation, a reduction in a workload capacity is determined.

Block 1020 may be followed by block 1022. At block 1022, in response to the reduction in the workload capacity, a request to the coordinator node for a reassignment of one or more of subzones of the first zone or the second zone is sent to another virtual-experience server.

Block 1022 may be followed by block 1024. At block 1024, in response to a recovery of the second virtual-experience server, current state information associated with the at least one subzone of the second zone is sent to one or more of the second virtual-experience server or the coordinator node.

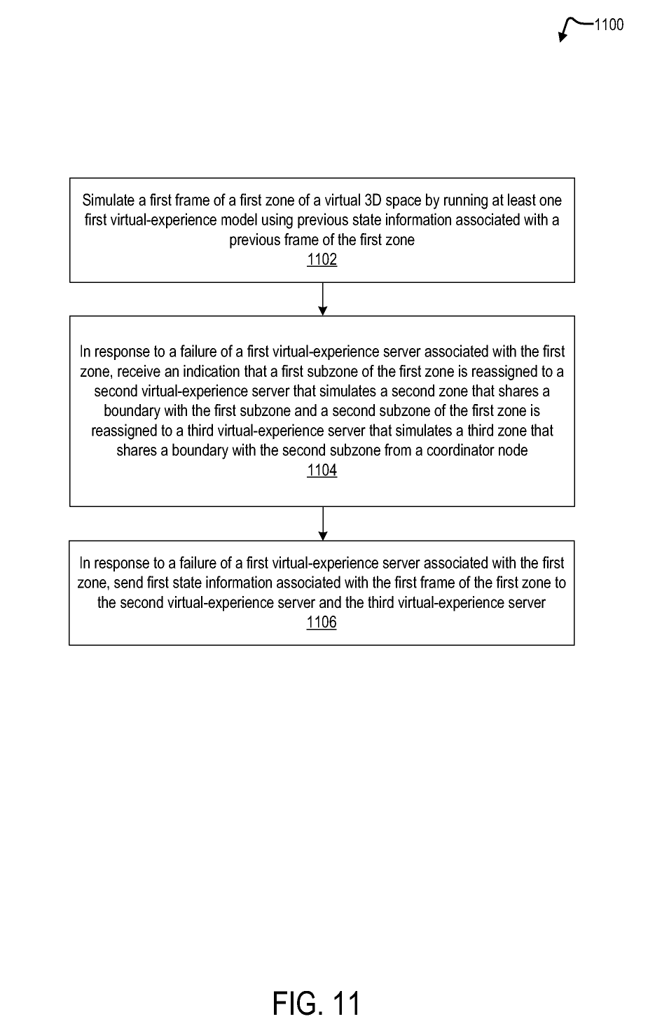

### FIG. 11: Second Example Method of Simulation Recovery by a Client Device

FIG. 11 is a flowchart of a second example method 1100 to perform simulation recovery by a client device, in accordance with some implementations.

In some implementations, some or all of the method 1100 can be implemented on one or more client devices 110 as shown in FIG. 1, on one or more developer devices (not illustrated), or on one or more server device(s), and/or on a combination of developer device(s), server device(s) and client device(s). In described examples, the implementing system includes one or more digital processors or processing circuitry (“processors”), and one or more storage devices (e.g., a data store 108 or other storage). In some implementations, different components of one or more servers and/or clients can perform different blocks or other parts of the method 1100. In some examples, a coordinator node is described as performing blocks of method 1100. Some implementations can have one or more blocks of method 1100 performed by one or more other devices (e.g., other client devices or server devices) that can send results or data to the first device.

In some implementations, method 1100, or portions of the method(s) described herein, can be initiated automatically by a system. In some implementations, the implementing system is a device. For example, the method (or portions thereof) can be periodically performed, or performed based on one or more particular events or conditions, e.g., the failure of a virtual-experience server, check point intervals, and/or one or more other conditions occurring which can be specified in settings read by the methods.

Referring to FIG. 11, the method 1100 may begin at block 1102. At block 1102, a first frame of a first zone of a virtual 3D space is simulated by running at least one first virtual-experience model using previous state information associated with a previous frame of the first zone.

Block 1102 may be followed by block 1104. At block 1104, in response to a failure of a first virtual-experience server associated with the first zone, an indication that a first subzone of the first zone is reassigned to a second virtual-experience server that simulates a second zone that shares a boundary with the first subzone and a second subzone of the first zone is reassigned to a third virtual-experience server that simulates a third zone that shares a boundary with the second subzone is received from a coordinator node.

Block 1104 may be followed by block 1106. At block 1106, in response to a failure of a first virtual-experience server associated with the first zone, first state information associated with the first frame of the first zone is sent to the second virtual-experience server and the third virtual-experience server.

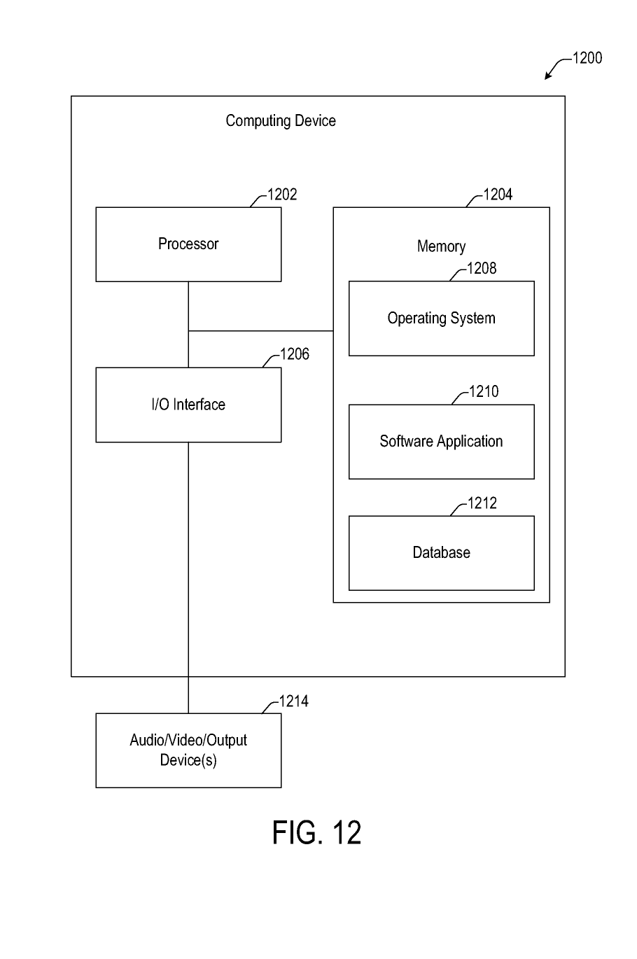

### FIG. 12: Computing Devices

Hereinafter, a more detailed description of various computing devices that may be used to implement different devices and/or components illustrated in FIG. 1 is provided with reference to FIG. 12.

FIG. 12 is a block diagram of an example computing device 1200 which may be used to implement one or more features described herein, in accordance with some implementations. In one example, computing device 1200 may be used to implement a computer device, (e.g., 102, 110 of FIG. 1), and perform appropriate operations as described herein. Computing device 1200 can be any suitable computer system, server, or other electronic or hardware device. For example, the computing device 1200 can be a mainframe computer, desktop computer, workstation, portable computer, or electronic device (portable device, mobile device, cell phone, smart phone, tablet computer, television, TV set top box, personal digital assistant (PDA), media player, game device, wearable device, etc.). In some implementations, computing device 1200 includes a processor 1202, a memory 1204, input/output (I/O) interface 1206, and audio/video input/output devices 1214 (e.g., display screen, touchscreen, display goggles or glasses, audio speakers, headphones, microphone, etc.).

Processor 1202 can be one or more processors and/or processing circuits to execute program code and control basic operations of the computing device 1200. A “processor” includes any suitable hardware and/or software system, mechanism or component that processes data, signals or other information. A processor may include a system with a general-purpose central processing unit (CPU), multiple processing units, dedicated circuitry for achieving functionality, or other systems. Processing need not be limited to a particular geographic location or have temporal limitations. For example, a processor may perform its functions in “real-time,” “offline,” in a “batch mode,” etc. Portions of processing may be performed at different times and at different locations, by different (or the same) processing systems. A computer may be any processor in communication with a memory.

Memory 1204 is typically provided in computing device 1200 for access by the processor 1202, and may be any suitable processor-readable storage medium, e.g., random access memory (RAM), read-only memory (ROM), Electrical Erasable Read-only Memory (EEPROM), Flash memory, etc., suitable for storing instructions for execution by the processor, and located separate from processor 1202 and/or integrated therewith. Memory 1204 can store software operating on the computing device 1200 by the processor 1202, including an operating system 1208, software application 1210 and associated database 1212. In some implementations, the software application 1210 can include instructions that enable processor 1202 to perform the functions described herein. Software application 1210 may include some or all of the functionality required to perform simulation recovery. In some implementations, one or more portions of software application 1210 may be implemented in dedicated hardware such as an application-specific integrated circuit (ASIC), a programmable logic device (PLD), a field-programmable gate array (FPGA), a machine learning processor, etc. In some implementations, one or more portions of software application 1210 may be implemented in general purpose processors, such as a central processing unit (CPU) or a graphics processing unit (GPU). In various implementations, suitable combinations of dedicated and/or general-purpose processing hardware may be used to implement software application 1210.

For example, software application 1210 stored in memory 1204 can include instructions for retrieving user data, for performing simulation recovery, and/or other functionality or software such as the simulation-recovery component 130, virtual experience engine 104, and/or virtual experience application 112. Any of the software in memory 1204 can alternatively be stored on any other suitable storage location or computer-readable medium. In addition, memory 1204 (and/or other connected storage device(s)) can store instructions and data used in the features described herein. Memory 1204 and any other type of storage (magnetic disk, optical disk, magnetic tape, or other tangible media) can be considered “storage” or “storage devices.”

I/O interface 1206 can provide functions to enable interfacing the computing device 1200 with other systems and devices. For example, network communication devices, storage devices (e.g., memory and/or data store 106), and input/output devices can communicate via I/O interface 1206. In some implementations, the I/O interface 1206 can connect to interface devices including input devices (keyboard, pointing device, touchscreen, microphone, camera, scanner, etc.) and/or output devices (display device, speaker devices, printer, motor, etc.).

For ease of illustration, FIG. 12 shows one block for each of processor 1202, memory 1204, I/O interface 1206, software blocks (e.g., operating system 1208 and software application) 1210, and database 1212. These blocks may represent one or more processors or processing circuitries, operating systems, memories, I/O interfaces, applications, and/or software modules. In other implementations, computing device 1200 may not have all of the components shown and/or may have other elements including other types of elements instead of, or in addition to, those shown herein. While the online virtual experience server 102 are described as performing operations as described in some implementations herein, any suitable component or combination of components of online virtual experience server 102, or similar system, or any suitable processor or processors associated with such a system, may perform the operations described.

A user device can also implement and/or be used with features described herein. Example user devices can be computer devices including some similar components as the computing device 1200, e.g., processor(s) 1202, memory 1204, and I/O interface 1206. An operating system, software and applications suitable for the client device can be provided in memory and used by the processor. The I/O interface for a client device can be connected to network communication devices, as well as to input and output devices, e.g., a microphone for capturing sound, a camera for capturing images or video, audio speaker devices for outputting sound, a display device for outputting images or video, or other output devices. A display device within the audio/video input/output devices 1214, for example, can be connected to (or included in) the computing device 1200 to display images pre- and post-processing as described herein, where such display device can include any suitable display device, e.g., an liquid crystal display (LCD), light-emitting diode (LED), or plasma display screen, cathode ray tube (CRT), television, monitor, touchscreen, 3D display screen, projector, or other visual display device. Some implementations can provide an audio output device, e.g., voice output or synthesis that speaks text.

The methods, blocks, and/or operations described herein can be performed in a different order than shown or described, and/or performed simultaneously (partially or completely) with other blocks or operations, where appropriate. Some blocks or operations can be performed for one portion of data and later performed again, e.g., for another portion of data. Not all of the described blocks and operations need be performed in various implementations. In some implementations, blocks and operations can be performed multiple times, in a different order, and/or at different times in the methods.

In some implementations, some or all of the methods can be implemented on a system such as one or more client devices. In some implementations, one or more methods described herein can be implemented, for example, on a server system, and/or on both a server system and a client system. In some implementations, different components of one or more servers and/or clients can perform different blocks, operations, or other parts of the methods.

One or more methods described herein (e.g., methods 600, 700, 800, 900, 1000, and 1100) can be implemented by computer program instructions or code, which can be executed on a computer. For example, the code can be implemented by one or more digital processors (e.g., microprocessors or other processing circuitry), and can be stored on a computer program product including a non-transitory computer readable medium (e.g., storage medium), e.g., a magnetic, optical, electromagnetic, or semiconductor storage medium, including semiconductor or solid state memory, magnetic tape, a removable computer diskette, a random access memory (RAM), a read-only memory (ROM), flash memory, a rigid magnetic disk, an optical disk, a solid-state memory drive, etc. The program instructions can also be contained in, and provided as, an electronic signal, for example in the form of software as a service (SaaS) delivered from a server (e.g., a distributed system and/or a cloud computing system). Alternatively, one or more methods can be implemented in hardware (logic gates, etc.), or in a combination of hardware and software. Example hardware can be programmable processors (e.g. Field-Programmable Gate Array (FPGA), Complex Programmable Logic Device), general purpose processors, graphics processors, Application Specific Integrated Circuits (ASICs), and the like. One or more methods can be performed as part of or component of an application running on the system, or as an application or software running in conjunction with other applications and operating system.

One or more implementations described herein may utilize user data, e.g., an image or video of a user’s face, user’s head, user’s body, etc. captured by using a camera and utilized by a virtual experience platform to render an avatar associated with the user. Some implementations may utilize audio provided by the user, text provided by the user, or other media provided by the user. Capture, storage, and use of user provided data (images, video, audio, text, other media, etc.) is made in accordance with user-specified preferences (e.g., capture, store, and use only on client device; on a server device; or both) and parameters (e.g., duration of storage, etc.). Additionally, user provided data is utilized in accordance with applicable laws and regulations, e.g., related to user privacy, user safety etc. Options are provided to the user to enable them to control whether and how the virtual experience platform may capture, store, and/or utilize user provided data. Additionally, user provided data are treated (e.g., subjected to aggregation, obfuscation, etc.) in such a way that the data cannot be linked back to the user (e.g., identify the user). Appropriate encryption technologies are utilized for data, whether in storage, during transfer over a network or other interface, or in memory, during use. The user provided data are used specifically for the purposes of providing a virtual experience for the user avatar.

One or more methods described herein can be run in a standalone program that can be run on any type of computing device, a program run on a web browser, a mobile application (“app”) executing on a mobile computing device (e.g., cell phone, smart phone, tablet computer, wearable device (wristwatch, armband, jewelry, headwear, goggles, glasses, etc.), laptop computer, etc.). In one example, a client/server architecture can be used, e.g., a mobile computing device (as a client device) sends user input data to a server device and receives from the server the live feedback data for output (e.g., for display). In another example, computations can be split between the mobile computing device and one or more server devices.

Although the description has been described with respect to particular implementations thereof, these particular implementations are merely illustrative, and not restrictive. Concepts illustrated in the examples may be applied to other examples and implementations.

Note that the functional blocks, operations, features, methods, devices, and systems described in the present disclosure may be integrated or divided into different combinations of systems, devices, and functional blocks as would be known to those skilled in the art. Any suitable programming language and programming techniques may be used to implement the routines of particular implementations. Different programming techniques may be employed, e.g., procedural or object-oriented. The routines may execute on a single processing device or multiple processors. Although the steps, operations, or computations may be presented in a specific order, the order may be changed in different particular implementations. In some implementations, multiple steps or operations shown as sequential in this specification may be performed at the same time.

What is claimed is:

1. A computer-implemented method of a coordinator node, comprising:
causing, by a processor, a first virtual-experience server to simulate a first region of a virtual three-dimensional (3D) space and a second virtual-experience server to simulate a second region of the virtual 3D space, wherein the first virtual-experience server simulates a first frame of the first region by running at least one first virtual-experience model using previous state information associated with a previous frame of the first region, and the second virtual-experience server simulates another first frame of the second region by running at least one second virtual-experience model using other previous state information associated with another previous frame of the second region;
in response to the first frame and the another first frame corresponding to a first checkpoint interval,
receiving, by the processor, first state information associated with the first frame from the first virtual-experience server and other first state information associated with the another first frame from the second virtual-experience server; and
storing, by the processor, the first state information and the other first state information; and
in response to a failure of the second virtual-experience server before simulation of another second frame of the second region,
causing, by the processor, the first virtual-experience server to perform recovery simulation for the second region based on the other first state information, wherein the first virtual-experience server performs the recovery simulation by running the at least one second virtual-experience model using the other first state information.

2. The computer-implemented method of claim 1, wherein:
each region is associated with at least one corresponding physics island,
each physics island is formed by one or more connected objects and at least one corresponding virtual-experience script associated with the one or more connected objects, and
a computational workload associated with simulating the one or more connected objects is associated with spatial locality.

3. The computer-implemented method of claim 1, further comprising:
receiving, by the processor, at least one inter-zone message associated with at least one object located in the second region from a third virtual-experience server; and
storing, by the processor, the at least one inter-zone message until a subsequent checkpoint interval.

4. The computer-implemented method of claim 3, wherein causing the first virtual-experience server to perform the recovery simulation for the second region comprises:
sending, by the processor, the other first state information and the at least one inter-zone message to first virtual-experience server; and
causing, by the processor, the first virtual-experience server to perform recovery simulation for the second region based on the other first state information and the at least one inter-zone message, wherein the first virtual-experience server performs the recovery simulation by running the at least one second virtual-experience model using the other first state information and the at least one inter-zone message.

5. The computer-implemented method of claim 1, further comprising:
in response to receiving the first state information and the other first state information, deleting, by the processor, the previous state information and the other previous state information, wherein the previous state information and the other previous state information are associated with a previous checkpoint interval.

6. The computer-implemented method of claim 1, further comprising:
receiving, by the processor, an indication of acceptance of the second region for simulation from the first virtual-experience server; and
in response to receiving the indication, sending, by the processor, a list of at least one other virtual-experience server that stores replicated state information for the second region of the virtual 3D space to the first virtual-experience server.

7. The computer-implemented method of claim 6, further comprising:
in response to the failure of the second virtual-experience server, sending, by the processor, an indication that the second region of the virtual 3D space is reassigned to the first virtual-experience server to at least one client device simulating the second region.

8. The computer-implemented method of claim 1, wherein:
the coordinator node comprises one or more virtual 3D space servers, or
the coordinator node comprises one or more storage devices.

9. A computer-implemented method of a virtual-experience server, comprising:
simulating, by a processor, a first frame of a first region of a virtual three-dimensional (3D) space by running at least one first virtual-experience model using previous state information associated with a previous frame of the first region;
in response to the first frame corresponding to a first checkpoint interval,
sending, by the processor, first state information associated with the first frame to a coordinator node;
in response to a failure of a second virtual-experience server before simulation of another first frame of a second region,
receiving, by the processor, a reassignment of the second region for simulation from the coordinator node;
receiving, by the processor, other previous state information associated with another previous frame of the second region from the coordinator node; and
performing, by the processor, a recovery simulation of the second region by running a second virtual-experience model using the other previous state information.

10. The computer-implemented method of claim 9, wherein:
each region of the virtual 3D space is associated with at least one corresponding physics island,
each physics island is formed by one or more connected objects and at least one corresponding virtual-experience script associated with the one or more connected objects, and
a computational workload associated with simulating the one or more connected objects is associated with spatial locality.

11. The computer-implemented method of claim 9, further comprising:
in response to the failure of the second virtual-experience server before simulation of the another first frame of the second region, receiving, by the processor, at least one inter-region message associated with at least one object located in the second region from the coordinator node.

12. The computer-implemented method of claim 11, wherein performing the recovery simulation of the second region comprises:
simulating, by the processor, the another first frame of the second region by running the second virtual-experience model using the other previous state information and the at least one inter-region message.

13. The computer-implemented method of claim 9, further comprising:
in response to a recovery of the second virtual-experience server, sending, by the processor, current state information associated with the second region to one or more of the second virtual-experience server or the coordinator node.

14. The computer-implemented method of claim 9, further comprising:
after performing the recovery simulation, determining, by the processor, a reduction in a workload capacity.

15. The computer-implemented method of claim 14, further comprising:
in response to the reduction in the workload capacity, requesting, by the processor, a reassignment of one or more of the first region or the second region to another virtual-experience server.

16. The computer-implemented method of claim 9, further comprising:
sending, by the processor, an indication of acceptance of the second region for simulation to the coordinator node.

17. The computer-implemented method of claim 16, further comprising:
in response to the coordinator node receiving the indication, receiving, by the processor, a list of at least one other virtual-experience server that stores replicated state information for the second region from the coordinator node.

18. The computer-implemented method of claim 17, further comprising:
sending, by the processor, the replicated state information for the second region to the at least one other virtual-experience server.

19. A computer-implemented method of a client device, comprising:
simulating, by a processor, a first frame of a first region of a virtual three-dimensional (3D) space by running at least one first virtual-experience model using previous state information associated with a previous frame of the first region;
in response to a failure of a first virtual-experience server associated with the first region,
receiving, by the processor, an indication that the first region is reassigned to a second virtual-experience server; and
sending, by the processor, first state information associated with the first frame of the first region to the second virtual-experience server.

20. The computer-implemented method of claim 19, wherein:
each region is associated with at least one corresponding physics island,
each physics island is formed by one or more connected objects and at least one corresponding virtual-experience script associated with the one or more connected objects, and
a computational workload associated with simulating the one or more connected objects is associated with spatial locality.
